(19) United States
(12) Patent Application Publication
(10) Pub. No.: US 2024/0258143 A1
(43) Pub. Date: Aug. 1, 2024

(54) SUBSTRATE SUPPORT APPARATUS AND METHOD FOR MANUFACTURING SUBSTRATE USING THE SAME

(71) Applicants: LG Display Co., Ltd., Seoul (KR); SUNIC SYSTEM. LTD., Suwon-si (KR)

(72) Inventors: Dongwook KIM, Paju-si (KR); Jewook KIM, Paju-si (KR); Indeock HONG, Paju-sI (KR); Chansuk PARK, Suwon-si (KR); JaeKwang RYU, Paju-si (KR)

(73) Assignees: LG Display Co., Ltd., Seoul (KR); SUNIC SYSTEM. LTD., Suwon-si (KR)

(21) Appl. No.: 18/422,520

(22) Filed: Jan. 25, 2024

(30) Foreign Application Priority Data
Jan. 31, 2023 (KR) 10-2023-0012964

(51) Int. Cl. H01L 21/673; H01L 21/68; H10K 59/12; H10K 71/16

(52) U.S. Cl. CPC H01L 21/6734; H01L 21/68; H10K 71/166; H10K 59/1201

(57) ABSTRACT

A substrate support apparatus reduces sagging of a substrate. The substrate support apparatus includes a plurality of position adjusters arranged in parallel and spaced apart with respect to a first direction; and a plurality of supports connected to the plurality of position adjusters and configured to support a substrate, wherein the plurality of supports are spaced apart from each other under the substrate and are configured to support the substrate, and wherein the plurality of supports are configured to be raised by the plurality of position adjusters.

The present application claims the benefit of Korean Patent Application No. 10-2023-0012964, filed in Korea on Jan. 31, 2023, which is hereby incorporated by reference.

### BACKGROUND

### Technical Field

The present disclosure relates to a substrate support apparatus used for a display apparatus and a method for manufacturing a substrate using the same.

### Discussion of the Related Art

With development of an information society, a demand for a display apparatus to display images has increased. Accordingly, various display apparatuses, such as a liquid crystal display LCD apparatus, a plasma display panel PDP apparatus, an organic light emitting display OLED apparatus, and a quantum dot light emitting display QLED apparatus have been recently developed.

The organic light emitting display OLED apparatus may be manufactured using a substrate having an organic light emitting diode OLED, and the substrate may be manufactured through an OLED deposition equipment. The OLED deposition equipment is configured so that an organic material is evaporated from a source with a substrate inserted into a chamber, and the evaporated organic material is deposited on the substrate.

On the other hand, the substrate inserted into the chamber is fixed (or chucked) to a chucking plate configured to be lowered while being disposed on an upper side of the chamber under the condition that the edge of substrate is supported by a substrate holder inside the chamber. After an entire surface of the substrate is fixed (or chucked) to the chucking plate, the organic material is deposited on its opposite surface of the substrate being not chucked.

Recently, as the display apparatus is enlarged, the size of substrate is also enlarged. As the size of substrate becomes larger, a central portion of the substrate sags due to its own weight, whereby the substrate is not fixed (or chucked) to the chucking plate.

### SUMMARY

Accordingly, embodiments of the present disclosure are directed to a substrate support apparatus and a method for manufacturing a substrate using the same that substantially obviate one or more of the problems due to limitations and disadvantages of the related art.

An aspect of the present disclosure is to provide a substrate support apparatus capable of minimizing or reducing sagging of a substrate for a substrate manufacturing process and a method for manufacturing the substrate using the same.

Another aspect of the present disclosure is to provide a substrate support apparatus capable of minimizing or reducing sagging of a substrate and thus reducing a defect rate of the substrate and a method for manufacturing the substrate using the same.

A further aspect of the present disclosure is to provide a substrate support apparatus capable of reducing a production energy and a method for manufacturing the substrate using the same.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a substrate support apparatus comprises a plurality of position adjusters arranged in parallel and spaced apart with respect to a first direction; and a plurality of supports connected to the plurality of position adjusters and configured to support a substrate, wherein the plurality of supports are spaced apart from each other under the substrate and are configured to support the substrate, and wherein the plurality of supports are configured to be raised by the plurality of position adjusters.

In another aspect, a method for manufacturing a substrate comprises positioning a plurality of supports at a standby position so as not to overlap a substrate whose edge is supported on a substrate holder of a chamber; positioning the plurality of supports to a support position and lowering a chucking plate disposed on the substrate; supporting the substrate by raising the plurality of supports, and chucking the substrate to the chucking plate by applying a voltage to the chucking plate; lowering the support portions and moving the supports to the standby position; attaching a mask having an opening to the substrate by lowering the chucking plate, and evaporating an organic material from a source and depositing the organic material on the substrate; supporting the substrate, on which the organic material is deposited, by moving the plurality of support portions to the support position and then raising the supports; turning-off the voltage applied to the chucking plate; and supporting the edge of the substrate on which the organic material is deposited on the substrate holder by lowering the plurality of supports.

In another aspect, a method for manufacturing a substrate comprises positioning a plurality of pin assemblies at a standby position not overlapping a substrate whose edge is supported on a substrate holder of a chamber; rotating the plurality of pin assemblies to be positioned at a support position and lowering a chucking plate placed on the substrate; supporting the substrate by raising the plurality of pin assemblies, and chucking the substrate to the chucking plate by applying a voltage to the chucking plate; lowering and rotating the plurality of pin assemblies to be positioned at the standby position; attaching a mask having an opening to the substrate by lowering the chucking plate, and evaporating an organic material from a source and depositing the organic material on the substrate; supporting the substrate, on which the organic material is deposited, by moving the plurality of pin assemblies to the support position and then raising the pin assemblies; turning-off the voltage applied to the chucking plate; and supporting the edge of the substrate on which the organic material is deposited on the substrate holder by lowering the plurality of pin assemblies.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a perspective view illustrating a substrate support apparatus according to an example embodiment of the present disclosure;

FIG. 2 is a schematic plan view of FIG. 1;

FIG. 3 is a schematic side view of FIG. 1;

FIG. 4 is a cross-sectional view along I-I′ of FIG. 2;

FIG. 5 is a schematic enlarged view showing ‘A’ of FIG. 1;

FIG. 6 is a schematic side view of FIG. 5 in an aspect of an X-axis direction;

FIGS. 7A to 12B are schematic process diagrams illustrating a substrate manufacturing process using the substrate support apparatus according to an example embodiment of the present disclosure;

FIG. 13 is a perspective view illustrating a substrate support apparatus according to another example embodiment of the present disclosure;

FIG. 14 is a schematic plan view of FIG. 13;

FIG. 15 is a schematic side view of FIG. 13;

FIG. 16 is a cross-sectional view along II-II′ of FIG. 15; and

FIGS. 17 and 18 are schematic operation state diagrams for supporting a substrate by a substrate support apparatus according to another example embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example, and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where “comprise,” “have,” and “include” described in the present specification are used, another part may be added unless “only˜” is used. The terms of a singular form may include plural forms unless referred to the contrary.

In construing an element, the element is construed as including an error range although there is no explicit description.

In describing a position relationship, for example, when the position relationship is described as “upon˜,” “above˜,” “below˜,” and “next to˜,” one or more portions may be arranged between two other portions unless “just” or “direct” is used.

In describing a time relationship, for example, when the temporal order is described as “after˜,” “subsequent˜,” “next˜,” and “before˜,” a case which is not continuous may be included unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

“X-axis direction,” “Y-axis direction,” and “Z-axis direction” should not be construed as only a geometric relationship in which the relationship between each other is perpendicular and may mean a broader directionality within a range in which the configuration of the present disclosure can act functionally.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Hereinafter, a display apparatus according to the embodiments of the present disclosure and a multi-screen display apparatus comprising the same will be described in detail with reference to the accompanying drawings. In the drawings, the same or similar elements are denoted by the same reference numerals even though they are depicted in different drawings. The scale of the components illustrated in the drawing has a different scale from real one, for convenience of description, whereby it is not limited to the scale shown in the drawing.

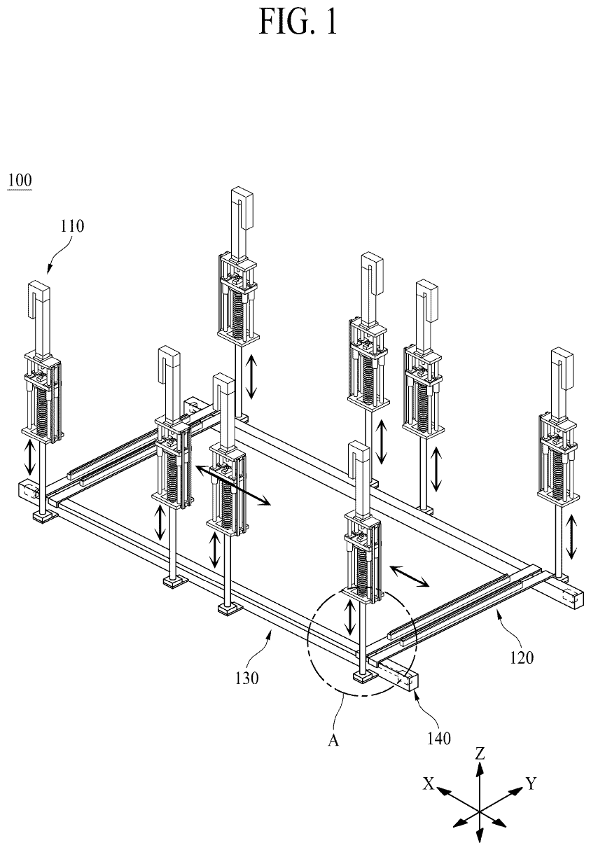

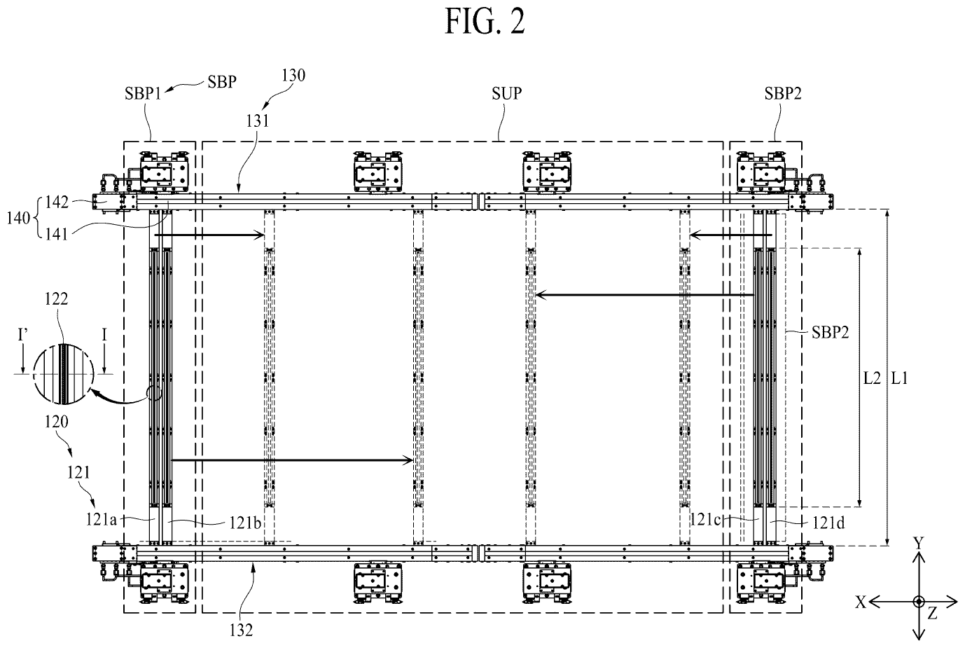

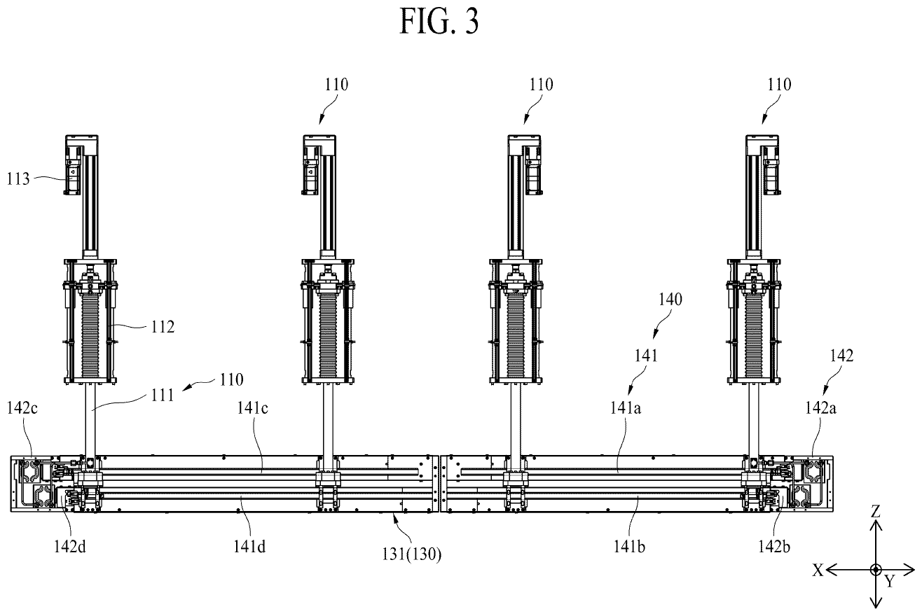

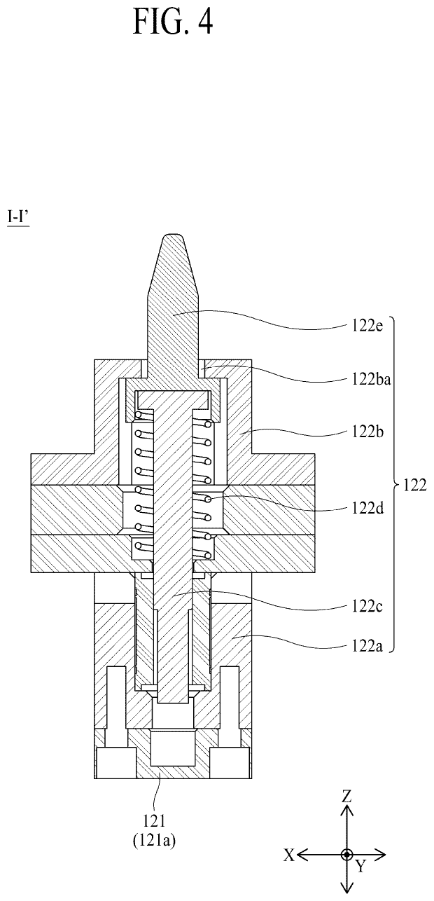

FIG. 1 is a perspective view illustrating a substrate support apparatus according to an example embodiment of the present disclosure, FIG. 2 is a schematic plan view of FIG. 1, FIG. 3 is a schematic side view of FIG. 1, and FIG. 4 is a cross-sectional view along I-I′ of FIG. 2.

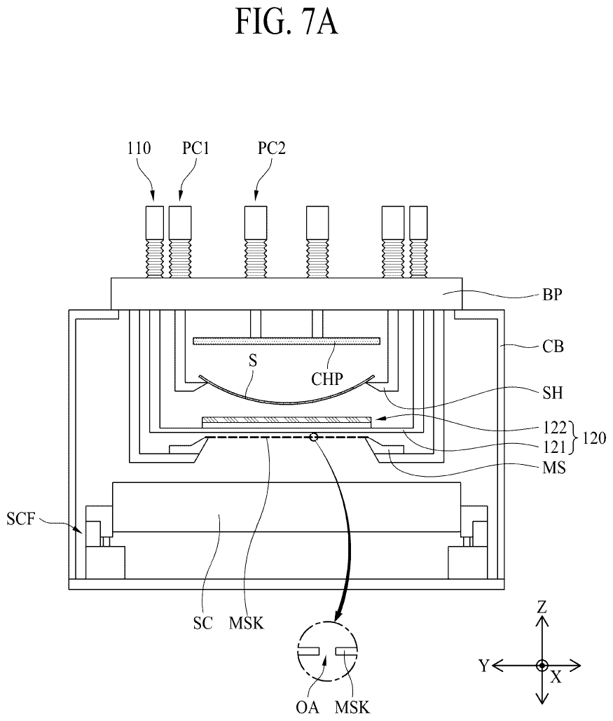

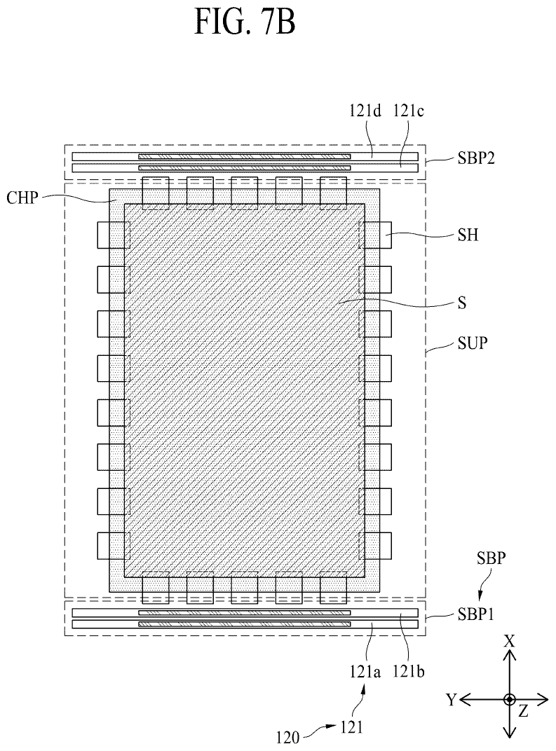

With reference to FIGS. 1 to 4, a substrate support apparatus 100 according to one embodiment of the present disclosure may include a plurality of position adjustment portions (position adjusters) 110 arranged in parallel in a first-axis direction X, and a plurality of support portions (supports) 120 connected to the plurality of position adjustment portions 110 and configured to support a substrate S (shown in FIG. 7A).

As shown in FIG. 1, the substrate support apparatus 100 according to one embodiment of the present disclosure may include eight position adjustment portions 110. Herein, the four position adjustment portions 110 are arranged along the first-axis direction X, and the other four position adjustment portions 110 may be arranged to face in a second-axis direction Y. Therefore, as shown in FIG. 1, a space into which a substrate S is to be inserted may be formed between each of the eight position adjustment portions 110. According to one embodiment of the present disclosure, the plurality of position adjustment portions 110 may raise or lower the plurality of support portions 120. For example, the plurality of position adjustment portions 110 according to one embodiment of the present disclosure may raise the plurality of support portions 120.

The plurality of support portions 120 according to one embodiment of the present disclosure may be spaced apart from each other under the substrate S in a support mode for supporting the substrate S. In this state, the plurality of support portions 120 may be raised by the plurality of position adjustment portions 110, to thereby evenly support a lower surface of the substrate S (or a central portion of the substrate S).

Therefore, the substrate support apparatus 100 according to one embodiment of the present disclosure may evenly support the lower surface (or central portion) of the substrate S even if the substrate S has a large size, so that it is possible to minimize, prevent, or at least reduce the central portion of the substrate S from sagging downward due to its own weight. Herein, the central portion of the substrate S may refer to remaining areas of the substrate S excluding the edge of the substrate S.

On the other hand, the plurality of support portions 120 may be disposed not to be lowered by the plurality of position adjustment portions 110 and not to be overlapped with the substrate S in a standby mode (or a standby mode in which the substrate S is not supported) before supporting the substrate S.

The substrate support apparatus 100 may further include a pair of guide portions (guides) 130. The pair of guide portions 130 may be configured to guide the movement of the plurality of support portions 120. The pair of guide portions 130 may be connected to each of the plurality of position adjustment portions 110 and the plurality of support portions 120. As shown in FIG. 1, the pair of guide portions 130 may be disposed along the first-axis direction X and may be spaced apart from each other in the second-axis direction Y. Accordingly, the plurality of support portions 120 may be moved in the first-axis direction X by the pair of guide portions 130. The plurality of support portions 120 may be moved in the first-axis direction X by receiving a driving force through a plurality of rotation driving portions.

As shown in FIG. 2, the pair of guide portions 130 may include a plurality of standby positions SBP in which the plurality of support portions 120 are located before supporting the substrate S and a support position SUP in which the plurality of support portions 120 support the substrate. The support position SUP may be located between the plurality of standby positions SBP. For example, the plurality of standby positions SBP may include a first standby position SBP1 at one edge (or end) of each of the pair of guide portions 130 and a second standby position SBP2 at the other edge of each of the pair of guide portions 130. The support position SUP may be disposed between the first standby position SBP1 and the second standby position SBP2.

Accordingly, the first-axis direction X may be a direction including the support position SUP in which the plurality of support portions 120 support the substrate and the standby position SBP in which the plurality of support portions 120 do not support the substrate, but not limited thereto. The second-axis direction Y may be a direction including the support position SUP and the standby position SBP.

As shown in FIGS. 1 and 2, the plurality of support portions 120 according to one embodiment of the present disclosure may be disposed in the second-axis direction Y intersecting the first-axis direction X. In this case, one side of each of the plurality of support portions 120 may be movably connected to one guide portion in the pair of guide portions 130, and the other side of each of the plurality of support portions 120 may be movably connected to the other guide portion in the pair of guide portions 130.

Accordingly, the plurality of position adjustment portions 110 raise the pair of guide portions 130, to thereby raise the plurality of support portions 120 connected to the pair of guide portions 130. As shown in FIGS. 1 and 2, the plurality of position adjustment portions 110 according to one embodiment of the present disclosure may be spaced apart from each other along the pair of guide portions 130.

The substrate support apparatus 100 according to one embodiment of the present disclosure may further include the plurality of rotation driving portions (rotation driver) 140.

The plurality of rotation driving portions 140 according to one embodiment of the present disclosure may be disposed in each of the pair of guide portions 130 and may be configured to provide a driving force for moving the plurality of support portions 120 in the first-axis direction X. For example, as shown in FIG. 2, each of the plurality of rotation driving portions 140 may include a ball screw 141 disposed in each of the pair of guide portions 130 and a rotation motor 142 coupled to one side of the ball screw 141 and configured to rotate the ball screw 141. According to one embodiment of the present disclosure, the rotation motor 142 rotates the ball screw 141 in a clockwise direction, whereby the plurality of support portions 120 connected to the ball screw 141 move from the standby position SBP to the support position SUP. According to one embodiment of the present disclosure, the rotation motor 142 rotates the ball screw 141 in a counterclockwise direction, whereby the plurality of support portions 120 connected to the ball screw 141 move from the support position SUP to the standby position SBP. According to another embodiment of the present disclosure, the rotation motor 142 rotates the ball screw 141 in a clockwise direction, whereby the plurality of support portions 120 connected to the ball screw 141 move from the support position SUP to the standby position SBP. Also, the rotation motor 142 rotates the ball screw 141 in a counterclockwise direction, whereby the plurality of support portions 120 connected to the ball screw 141 move from the standby position SBP to the support position SUP.

On the other hand, the number of rotations of the ball screw 141 may be determined according to the driving force provided by the rotation motor 142, and the movement distance of each of the plurality of support portions 120 may vary according to the number of rotations of the ball screw 141. For example, as the number of rotations of the ball screw 141 increases, the movement distance of each of the plurality of support portions 120 may be increased. Therefore, as shown in FIG. 2, the positions of the plurality of support portions 120 may be different from each other in the support position SUP. As a result, each of the plurality of support portions 120 may be moved by each of the plurality of rotation driving portions 140 and may be disposed to be spaced apart from each other.

Therefore, as shown in FIG. 2, the substrate support apparatus 100 according to one embodiment of the present disclosure may uniformly support the lower surface of the substrate S because the plurality of support portions 120 are disposed to be spaced apart from each other within the support position SUP so that it is possible to minimize, prevent, or at least reduce sagging of the substrate (or large-sized substrate).

When the sagging of the substrate (or large-sized substrate) is minimized, prevented, or reduced, the separation distance between the substrate (or large-sized substrate) and the chucking plate CHP may be reduced, whereby the entire surface of the large-sized substrate may be fixed (or chucked) to the chucking plate by the static electricity of the chucking plate. Accordingly, because the organic material evaporated by the source may be uniformly deposited on the substrate (or large-sized substrate) evenly fixed to the chucking plate for a subsequent process, thereby enabling a reduction of the manufacturing defect rate of the substrate. Furthermore, as the defect rate of the substrate is reduced, overall production energy may be reduced.

Hereinafter, the plurality of position adjustment portions 110, the plurality of support portions 120, the pair of guide portions 130, and the plurality of rotation driving portions 140 in the substrate support apparatus 100 according to one embodiment of the present disclosure will be described in detail with reference to FIGS. 2 and 3.

Each of the plurality of position adjustment portions 110 according to one embodiment of the present disclosure may include an elevating shaft 111, a bellows 112, and a cylinder pump 113. As shown in FIG. 2, one pair of guide portions 130 according to one embodiment of the present disclosure may include a first guide portion 131 and a second guide portion 132 arranged in parallel along the first-axis direction X.

The elevating shaft 111 may be coupled to each of the pair of guide portions 130. The elevating shaft 111 according to one embodiment of the present disclosure may be provided in the form of circular pipe, and one edge of the elevating shaft may be coupled to each of the pair of guide portions 130 through a fastening member, such as a bolt. Therefore, the elevating shaft 111 is raised in the third-axis direction Z by the cylinder pump 113, thereby elevating the pair of guide portions 130.

Meanwhile, the elevating shaft 111 in each of the plurality of position adjustment portions 110 may be coupled to the outside of the first guide portion 131 and the outside of the second guide portion 132 to be spaced apart from each other as shown in FIG. 2. For example, the four elevating shafts 111 may be coupled to the outer side (or the outer side surface) of the first guide portion 131 while being spaced apart from each other. Also, the four elevating shafts 111 may be coupled to the outside (or the outer side surface) of the second guide portion 132 while being spaced apart from each other.

The outer side of the first guide portion 131 may indicate an outer surface opposite to the inside of the first guide portion 131 on which the plurality of support portions 120 are disposed. The outer side of the second guide portion 132 may indicate an outer surface opposite to the inner of the second guide portion 132 on which the plurality of support portions 120 are disposed. Accordingly, as shown in FIG. 2, the elevating shaft 111 in each of the plurality of position adjustment portions 110 is disposed outside the pair of guide portions 130, whereby the elevating shaft 111 may not interfere with the plurality of support portions 120 moving in the first-axis direction X. At least a portion of the elevating shaft 111 of each of the plurality of position adjustment portions 110 may be disposed inside a chamber CB (shown in FIG. 7A) in a vacuum state. Also, the plurality of support portions 120, the pair of guide portions 130, and the plurality of rotation driving portions 140 may be disposed inside the chamber CB.

The bellows 112 may be coupled to the elevating shaft 111 and may be configured to locally surround the elevating shaft 111. The bellows 112 is configured to maintain a pressure difference between the chamber CB (shown in FIG. 7A) of the vacuum state and the atmospheric pressure outside the chamber. The bellows 112 according to one embodiment of the present disclosure may be disposed outside the chamber CB. For example, the bellows 112 may be arranged on a base plate BP coupled to an upper side of the chamber CB. As described above, because the elevating shaft 111 is raised by the cylinder pump 113, the inside of the chamber CB cannot be maintained in the vacuum state when a portion of the chamber CB, to which the elevating shaft 111 is movably connected, communicates with the outside. Therefore, the bellows 112 may be provided in such a way that a portion where the base plate BP and the elevating shaft 111 are connected to each other is sealed. For example, the bellows 112 may be provided in the form of corrugated circular accordion.

The cylinder pump 113 may be disposed on the bellows 112 and may be configured to raise (or elevate) the elevating shaft 111. According to one embodiment of the present disclosure, the cylinder pump 113 may be coupled to ¬-shaped cylinder housing and may be configured to provide a driving force capable of elevating the elevating shaft 111. For example, the ball screw connected to the cylinder pump may be rotated according to the driving force provided by the cylinder pump 113, whereby a cylinder rod connected to the ball screw may be elevated. As the cylinder rod elevates, the elevating shaft 111 connected to the cylinder rod may be elevated.

Therefore, in the substrate support apparatus 100 according to one embodiment of the present disclosure, each of the plurality of position adjustment portions 110 may elevate the pair of guide portions 130 in the third-axis direction Z.

With reference once again to FIGS. 1 to 4, each of the plurality of support portions 120 may include a support frame 121 and a support member 122.

The support frame 121 may be movably coupled to each of the pair of guide portions 130. The support frame 121 according to one embodiment of the present disclosure may comprise a first support frame 121a disposed at one edge of the pair of guide portions 130, a second support frame 121b disposed closer to the other edge of the pair of guide portions 130 than the first support frame 121a, a third support frame 121c disposed closer to the other edge of the pair of guide portions 130 than the second support frame 121b, and a fourth support frame 121d disposed closer to the other edge of the pair of guide portions 130 than the third support frame 121c. Herein, one edge of the pair of guide portions 130 may refer to a lower edge portion in the first-axis direction X with respect to FIG. 2, and the other edge of the pair of guide portions 130 may refer to an upper edge portion of the first-axis direction X with respect to FIG. 2.

As shown in a dotted line of FIG. 2, the first support frame 121a, the second support frame 121b, the third support frame 121c, and the fourth support frame 121d may be spaced apart from each other in the support position SUP for the support mode for supporting the substrate S. Accordingly, the substrate support apparatus 100 according to one embodiment of the present disclosure may evenly support the entire lower surface of the substrate S (or central portion of the substrate) by the use of first to fourth support frames 121a, 121b, 121c and 121d even if the substrate S is large-sized, so that the entire surface of the substrate (or large-sized substrate) may be attached to or fixed to the chucking plate CHP. Therefore, the substrate support apparatus 100 according to one embodiment of the present disclosure may allow the entire surface of the substrate (or large-sized substrate) to be evenly fixed to the chucking plate CHP, so that the organic material may be uniformly deposited on the substrate (or large-sized substrate) in the subsequent process, thereby improving the quality of substrate (or large-sized substrate) which has been completely manufactured.

On the other hand, the first support frame 121a, the second support frame 121b, the third support frame 121c, and the fourth support frame 121d may be arranged to be adjacent to each other in the standby position SBP for the standby mode in which the substrate S is not supported. For example, the first support frame 121a and the second support frame 121b may be located in the first standby position SBP1 before supporting the substrate S, and the third support frame 121c and the fourth support frame 121d may be located in the second standby position SBP2 before supporting the substrate S. Therefore, the substrate support apparatus 100 according to one embodiment of the present disclosure does not interfere with the first to fourth support frames 121a, 121b, 121c and 121d in the process of depositing the organic material on the substrate S so that it is possible to reduce or prevent the defect rate of the substrate S.

Each of the first to fourth support frames 121a, 121b, 121c and 121d may be moved to the standby position SBP and the support position SUP by the driving force provided by the plurality of rotation driving portions 140. For example, the rotation driving portion 140 may include the ball screw 141 and the rotation motor 142.

Meanwhile, the first to fourth support frames 121a, 121b, 121c and 121d are movably coupled to the pair of guide portions 130. Thus, the first to fourth support frames 121a, 121b, 121c and 121d may be elevated together with the pair of guide portions 130 when the pair of guide portions 130 are elevated by the plurality of position adjustment portions 110.

The support member 122 may be coupled to the support frame 121. The support member 122 according to one embodiment of the present disclosure may be coupled to the upper side of the support frame 121. For example, as shown in FIG. 4, the support member 122 may be coupled to the upper surface of the support frame 121 by a fastening member, such as a bolt in the third-axis direction Z.

The support member 122 according to one embodiment of the present disclosure may be arranged along a longitudinal direction of the support frame 121. For example, as shown in FIG. 2, the support member 122 may be coupled to the upper surface of the support frame 121 along the support frame 121 arranged in the second-axis direction Y. The support member 122 may have a length shorter than that of the support frame 121. For example, the support member 122 may be provided with a second length L2 which is shorter than a first length L1 of the support frame 121. If the length of the support member 122 is longer than the length of the support frame 121, the support member 122 may be in contact with the pair of guide portions 130, thereby restricting the movement of the support frame 121. Therefore, in case of the substrate support apparatus 100 according to one embodiment of the present disclosure, the support member 122 is shorter than the support frame 121, so that the support member 122 may not interfere with the movement of the support frame 121 moving along the first-axis direction X. The support member 122 may directly support the lower surface of the substrate S in the support position SUP for the support mode. Because the support member 122 is disposed in each of the plurality of support frames 121, the plurality of support members 122 may be provided. Further, each of the plurality of support members 122 may be disposed in each of the first support frame 121a, the second support frame 121b, the third support frame 121c, and the fourth support frame 121d. Therefore, each of the plurality of support members 122 may be disposed to be spaced apart from each other in the support position SUP for the support mode, so that the entire lower surface of the substrate S may be uniformly supported.

The support member 122 according to one embodiment of the present disclosure may include a housing 122a, a stopper 122b, a guide shaft 122c, an elastic member 122d, and a support bar 122e.

The housing 122a is positioned at the lowermost side of the support member 122 and may be coupled to the support frame 121 through a fastening member. The housing 122a may be coupled to the support frame 121 and may be configured to support the stopper 122b and the support bar 122e coupled to the upper side.

The stopper 122b may be coupled to the upper side of the housing 122a through a fastening member, such as a bolt or adhesive. According to one embodiment of the present disclosure, the stopper 122b is configured to prevent the guide shaft 122c, the elastic member 122d and the support bar 122e arranged therein from being separated therefrom and disposed outside (or outside) the stopper 122b. The stopper 122b may include a through hole 122ba. The through hole 122ba may be a hole formed through a central portion of the stopper 122b. As the support bar 122e is inserted into the through hole 122ba, the support bar 122e may partially protrude to the outside of the stopper 122b. The through hole 122ba may be provided as a hole smaller than one side of the support bar 122e coupled to the guide shaft 122c. Therefore, the stopper 122b may prevent the support bar 122e inserted into the through hole 122ba from being completely separated therefrom and disposed outside.

The guide shaft 122c may be movably coupled to the stopper 122b and the housing 122a. For example, each of the stopper 122b and the housing 122a may be provided with a cylindrical inner hole in which the guide shaft 122c may be moved in the third-axis direction Z, and the guide shaft 122c may be inserted into the cylindrical hole and may be moved in an up-and-down direction. The support bar 122e may be coupled to one side of the guide shaft 122c. When the substrate S is supported on the support bar 122e, the guide shaft 122e may be moved downward due to the load of the substrate S. For example, the guide shaft 122c may be moved downward as the support bar 122e supports the substrate S for the support mode. When the substrate S is not supported by the support bar 122e, the guide shaft 122e may be moved upward. For example, the guide shaft 122c may be moved in a downward direction as the support bar 122e does not support the substrate S in the standby mode. In this case, one side of the guide shaft 122c to which the support bar 122e is coupled may be thicker than a body. For example, one side of the guide shaft 122c may be provided to be larger than the size of the through hole 122ba. Accordingly, the guide shaft 122c is blocked by the stopper 122b, thereby preventing the guide shaft 122c from being separated from the stopper 122b.

The elastic member 122d may surround the guide shaft 122c and may be supported by one side of the guide shaft 122c and the housing 122a, respectively. The elastic member 122d according to one embodiment of the present disclosure surrounds the body of the guide shaft 122c and may be supported by one side of the guide shaft 122c and the housing 122a. Therefore, when the support bar 122e supports the substrate S, the guide shaft 122c may be moved downward by the load of the substrate S, thereby contracting the elastic member 122d. On the contrary, when the support bar 122e does not support the substrate S, the elastic member 122d may be stretched by the elastic restoring force, thereby moving the guide shaft 122c in the upward direction.

The support bar 122e may be coupled to one side of the guide shaft 122c and may be configured to face the elastic member 122d. As shown in FIG. 4, the support bar 122e according to one embodiment of the present disclosure may have a size gradually increasing from an upper side to a lower side, in which a size of a lower portion coupled to one side of the guide shaft 122c is larger than that of one side of the guide shaft 122c. Therefore, only the lower portion of the support bar 122e may be arranged inside the stopper 122b, and the remaining portions of the support bar 122e except for the lower portion may protrude to the outside through the through hole 122ba. The lower portion of the support bar 122e is provided to be larger than the size of one side of the guide shaft 122c (or size of the through hole 122ba). Thus, even if the support bar 122e is moved upward by the stretch of the elastic member 122d, the support bar 122e may not be separated from the stopper 122b.

Meanwhile, as shown in FIG. 4, because the support bar 122e is supported by the elastic member 122d, the support bar 122e may be moved downward when supporting the substrate S. Therefore, the substrate support apparatus 100 according to one embodiment of the present disclosure may absorb an impact, which is generated when the support member 122 supports the substrate S, by the elastic member 122d. Therefore, the substrate support apparatus 100 according to one embodiment of the present disclosure may minimize, prevent, or reduce damage, such as scratches on the substrate S, as compared to a case in which an elastic member is not provided and thus an impact is not absorbed.

The plurality of rotation driving portions 140 may include the ball screw 141 and the rotation motor 142 for providing rotation driving force to the ball screw 141.

As shown in FIG. 3, the ball screw 141 includes one pair of guide portions 130. For example, one of the pair of guide portions 130 may include a first ball screw 141a, a second ball screw 141b, a third ball screw 141c, and a fourth ball screw 141d, which are spaced apart from each other the first guide portion 131. The first ball screw 141a may be disposed relatively higher than the second ball screw 141b and may be arranged in line along the first-axis direction X together with the third ball screw 141c. The second ball screw 141b may be arranged in line at a diagonal direction with the third ball screw 141c and may be arranged in line along the first-axis direction X together with the fourth ball screw 141d.

The rotation motor 142 may include a first rotation motor 142a coupled to the first ball screw 141a and configured to provide rotation driving force, a second rotation motor 142b coupled to the second ball screw 141b and configured to provide rotation driving force, a third rotation motor 142c coupled to the third ball screw 141c and configured to provide rotation driving force, and a fourth rotation motor 142d coupled to the fourth ball screw 141d and configured to provide rotation driving force. As shown in FIG. 3, the first rotation motor 142a and the second rotation motor 142b may be vertically disposed at one side of the guide portion 130 and may be configured to provide the driving force to each of the first ball screw 141a and the second ball screw 142b. The third rotation motor 142c and the fourth rotation motor 142d may be vertically arranged at the other side of the guide portion 130 and may to configured to provide the driving force to each of the third ball screw 141c and the fourth ball screw 142d. Accordingly, the first ball screw 141a, the second ball screw 141b, the third ball screw 141c, and the fourth ball screw 141d may be independently driven, whereby the first support frame 121a connected to the first ball screw 141a, the second support frame 121b connected to the second ball screw 141b, the third support frame 121c connected to the third ball screw 141c, and the fourth support frame 121d connected to the fourth ball screw 141d may be independently moved by different distances as shown in FIG. 2.

The plurality of rotation driving portions 140 arranged in the first guide portion 131 have been described above. However, because the second guide portion 132 has the same structure as the first guide portion 131, the description of the second guide portion 132 is replaced with the description of the first guide portion 131.

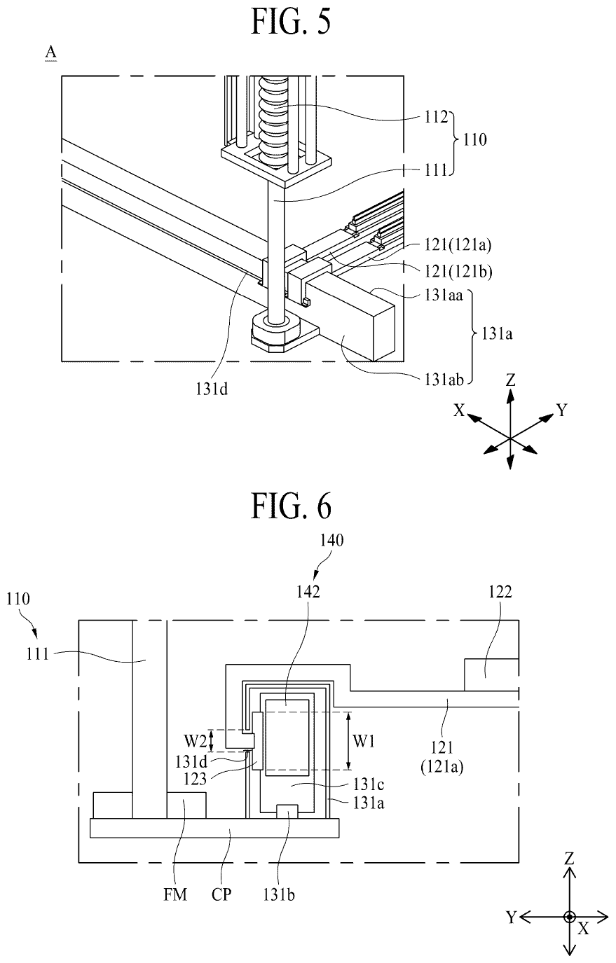

FIG. 5 is a schematic enlarged view showing ‘A’ of FIG. 1, and FIG. 6 is a schematic side view of FIG. 5 in an aspect of X-axis direction.

As illustrated in FIGS. 5 and 6, each of the pair of guide portions 130 may include a guide housing, an LM guide, and an LM block. For example, the first guide portion 131 may include a guide housing 131a, an LM guide 131b, and an LM block 131c.

The guide housing 131a is configured to prevent or reduce foreign matter, such as dust, which is generated by the friction of the ball screw 141 and the support frame 121 moving along a screw thread of the ball screw 141 when the plurality of rotation driving portions 140 arranged inside the first guide portion 131 are driven, from being scattered and diffused toward the substrate S. The guide housing 131a according to one embodiment of the present disclosure may be provided in the form of hollow rod. Because the plurality of rotation driving portions 140 are disposed inside the guide housing 131a, the guide housing 131a may prevent or reduce the foreign matter generated due to the friction from being scattered toward the substrate S.

The LM guide 131b may be coupled to the guide housing 131a. For example, the LM guide 131b may be coupled to an upper surface of a connection member CP to which the guide housing 131a is coupled. As shown in FIG. 6, the elevating shaft 111 may be coupled to the upper surface of the connection member CP at a position spaced apart from the LM guide 131b. The elevating shaft 111 may be coupled to the upper surface of the connection member CP by a fastening member FM. The LM guide 131b may be disposed below the ball screw 141 of the rotation driving portion 140 and may be provided along the longitudinal direction of the ball screw 141. Alternatively, the LM guide 131b may be disposed inside the guide housing 131a and may be provided along a direction in which the guide housing 131a is disposed. For example, the LM guide 131b may be arranged in the form of long rail along the first-axis direction X.

The LM block 131c may be movably coupled to the LM guide 131b and the ball screw 141. As shown in FIG. 6, the LM block 131c may be disposed on the upper surface of the LM guide 131b and may be configured to partially cover both side surfaces of the LM guide 131b. Although not shown, the LM block 131c may include an LM hole to which the ball screw 141 may be coupled. Therefore, the LM block 131c may be moved along the LM guide 131b according to the rotation of the ball screw 141. For example, the LM block 131c may be moved to the support position SUP and the standby position SBP along the first-axis direction X according to a direction in which the ball screw 141 is rotated by the rotation motor 142.

Meanwhile, each in the pair of guide portions 130 may further include a guide hole 131d into which one side or the other side of the support frame 121 is inserted. The guide hole 131d corresponds to a hole for guiding the movement of the support frame 121 and simultaneously connecting the support frame 121 to the LM block 131c. The guide hole 131d according to one embodiment of the present disclosure may be formed through the side surface of the guide housing 131a, as shown in FIG. 5. For example, the guide hole 131d may be formed on the other side 131ab of the guide housing 131a opposite to one side 131aa of the guide housing 131a in which the support member 122 is disposed. For example, the guide hole 131d may be formed in an outward direction in which the plurality of position adjustment portions 110 are disposed. Therefore, the substrate support apparatus 100 according to one embodiment of the present disclosure allows foreign matter, such as dust generated by the movement of the support member 122, to be scattered to the outside of the guide portion 130, thereby maximizing or at least increasing the prevention of contamination with respect to the substrate S.

As shown in FIG. 6, each of the plurality of support portions 120 may further include a separation preventing member 123 coupled to one side or the other side of the support frame 121 inserted into the guide hole 131d. The separation preventing member 123 according to one embodiment of the present disclosure may be disposed inside the guide housing 131a. As shown in FIG. 6, the separation preventing member 123 may be coupled to each of the support frame 121 and the LM block 131c. Therefore, the separation preventing member 123 and the support frame 121 may be moved together according to the movement of the LM block 131c.

With further reference to FIG. 6, a width W1 of the separation preventing member 123 may be greater than a width W2 of the guide hole 131d. Accordingly, even when the support frame 121 is moved in the second-axis direction Y, the movement of the second-axis direction Y may be restricted by the separation preventing member 123. Accordingly, the movement of the second-axis direction Y may be also restricted in the support member 122 coupled to the support frame 121, thereby minimizing, preventing, or at least reducing damage, such as scratches on the substrate S. As a result, the substrate support apparatus 100 according to one embodiment of the present disclosure is used to prevent or at least reduce the substrate S from sagging and being damaged for a manufacturing process, thereby improving the quality of the completed substrate S.

Hereinafter, a substrate manufacturing process according to an example embodiment of the present disclosure will be described in detail with reference to FIGS. 7A to 12B. The substrate manufacturing process according to one embodiment of the present disclosure may be performed using the substrate support apparatus 100 according to one embodiment of the present disclosure.

FIGS. 7A to 12B are schematic process diagrams illustrating the substrate manufacturing process using the substrate support apparatus according to an example embodiment of the present disclosure.

FIGS. 7A and 7B illustrate a step of inserting the substrate S into the chamber CB, supporting the edge of the substrate S on a plurality of substrate holders SH, and positioning the plurality of support portions 120 in the standby position SBP while being not overlapped with the substrate S. FIG. 7A is a schematic side view in an aspect of first-axis direction X, and FIG. 7B is a schematic plan view in an aspect of third-axis direction Z.

As shown in FIG. 7A, the plurality of substrate holders SH, the chucking plate CHP, the plurality of support portions 120, a mask MSK having an opening OA, a mask stage MS, a source SC, and a source fixing portion SCF may be disposed inside the chamber CB. The plurality of position adjustment portions 110 (or bellows 112 and cylinder pump 113) connected to the plurality of support portions 120 may be arranged on the upper surface of the base plate BP coupled to the upper side of the chamber CB. A first position control portion PC1 connected to the substrate holder SH may be disposed on the upper surface of the base plate BP, and a second position control portion PC2 connected to the chucking plate CHP may be disposed on the upper surface of the base plate BP. The first position control portion PC1 is configured to adjust the position of the substrate holder SH. For example, the first position control portion PC1 may elevate the substrate holder SH in the third-axis direction Z. The second position control portion PC2 is configured to adjust the position of the chucking plate CHP. For example, the second position control portion PC 2 may elevate the chucking plate CHP in the third-axis direction Z.

The mask stage MS may be configured to support the edge of the mask MSK and may be disposed between the source SC and the support portion 120 (or support frame 121).

The source SC may be configured to evaporate the organic material and may be disposed under the mask MSK while being overlapped with the substrate S and the mask MSK. The source fixing portion SCF is coupled to both sides of the source SC and the bottom surface of the chamber CB, to thereby fix the source SC to the inside of the chamber CB.

As shown in FIG. 7A, the substrate S is inserted into the chamber CB by a transfer portion (not shown), such as a robot, and then the edge of the substrate S is supported on the plurality of substrate holders SH disposed in the chamber CB. As described above, because the substrate S is large-sized, the central portion of the substrate S may sag down due to its own weight of the substrate S. Therefore, as shown in FIG. 7A, the edge of the substrate S is supported by the substrate holder SH and is provided in a concave shape.

In FIG. 7B, in the state shown in FIG. 7A, the plurality of support portions 120 are positioned in the standby position SBP while being not overlapped with the substrate S in the third-axis direction Z. The plurality of rotation driving portions 140 may be formed by moving the plurality of support portions 120 along the pair of guide portions 130 to the standby position SBP. Accordingly, the first support frame 121a and the second support frame 121b may be positioned in the first standby position SBP1, and the third support frame 121c and the fourth support frame 121d may be positioned in the second standby position SBP2. Therefore, the substrate S inserted into the chamber CB may be stably placed on the substrate holder SH without interfering with the first to fourth support frames 121a, 121b, 121c and 121d. As shown in FIG. 7B, the substrate S may be positioned within the support position SUP.

On the other hand, the chucking plate CHP may be configured to have a larger size than the substrate S and may be disposed on the upper side of the substrate S. This is for depositing the organic material on the substrate S which is evenly fixed to the chucking plate CHP by the static electricity. As described above, as the substrate S sags according to the increase in size of the substrate S, the substrate S may not be fixed or attached to the chucking plate CHP. In this case, even if the organic material deposition process is not performed or the organic material deposition process is performed, the defect rate of the completed substrate may be increased. However, the substrate support apparatus 100 according to one embodiment of the present disclosure supports the central portion of the substrate S before the substrate S is fixed or attached to the chucking plate CHP, so that the entire surface of the substrate S may be fixed or attached to the chucking plate CHP. Thus, the substrate support apparatus 100 according to one embodiment of the present disclosure may reduce the defect rate of the substrate S that has been completely manufactured, thereby resulting in reduction of production energy.

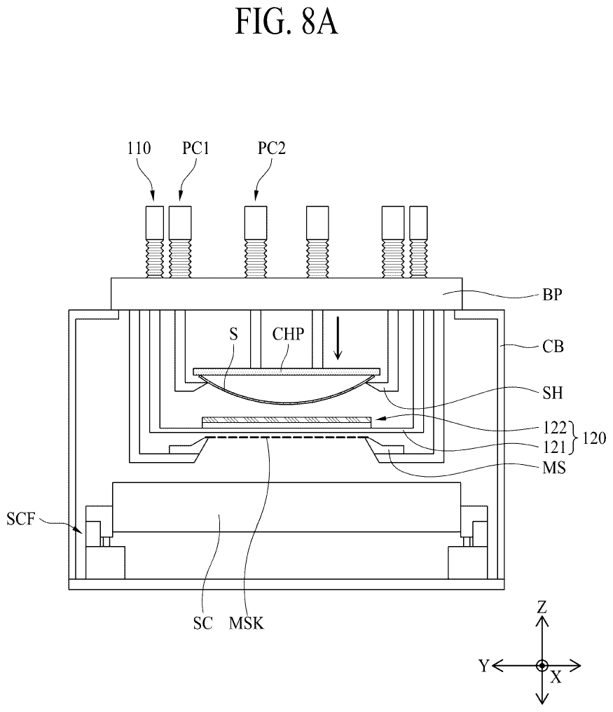

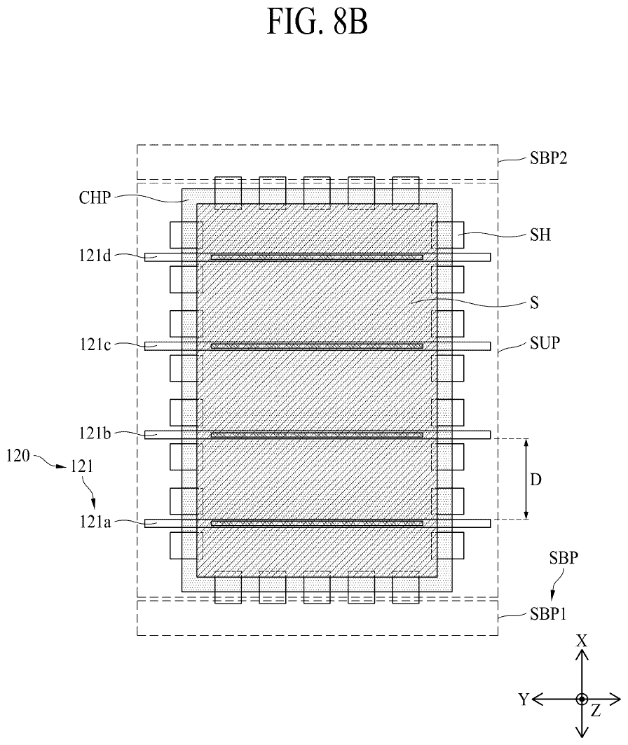

FIGS. 8A and 8B illustrate a step of positioning the plurality of support portions 120 in the support position SUP under the substrate S and lowering the chucking plate CHP placed on the substrate S. FIG. 8A is a schematic side view in an aspect of first-axis direction X, and FIG. 8B is a schematic plan view in an aspect of third-axis direction Z.

As shown in FIG. 8A, the chucking plate CHP may be lowered in a direction toward the substrate S by the plurality of second position control portions PC2. In this case, the chucking plate CHP may be positioned as close as possible to the edge of the substrate S so that it is possible to prevent or at least reduce the concavely provided edge of the substrate S from being damaged. As shown in FIG. 8A, because only the edge of the substrate S is supported by the substrate holder SH, the central portion of the substrate S may sag down due to its own weight. Thus, a first distance between the edge of the substrate S and the chucking plate CHP and a second distance between the central portion of the substrate S and the chucking plate CHP may be different from each other. For example, the second distance may be greater than the first distance. Therefore, when the same voltage (or static electricity) is applied to the entire chucking plate CHP, the edge of the substrate S may be stably attached to the chucking plate CHP, while the central portion of the substrate S may not be attached to the chucking plate CHP. In case of the substrate support apparatus 100 according to one embodiment of the present disclosure, because the plurality of support portions 120 support the sagging portion (central portion) of the substrate S before the voltage (or static electricity) is applied to the chucking plate CHP, the substrate S may be positioned close to the chucking plate CHP, whereby the entire surface of the substrate S may be uniformly attached to or fixed to the chucking plate CHP in the subsequent process.

In FIG. 8B, in the state as shown in FIG. 8A, the plurality of support portions 120 are positioned in the support position SUP such that the plurality of support portions 120 are spaced apart from each other under the substrate S. This may be performed by positioning the plurality of support portions 120 at the different positions within the support position SUP along the pair of guide portions 130 by the plurality of rotation driving portions 140. Accordingly, the first support frame 121a, the second support frame 121b, the third support frame 121c, and the fourth support frame 121d may be spaced apart from each other in the support position SUP. In this case, the first support frame 121a, the second support frame 121b, the third support frame 121c, and the fourth support frame 121d may be arranged at the same interval D within the support position SUP, but not limited thereto. In this case, each of the first support frame 121a, the second support frame 121b, the third support frame 121c, and the fourth support frame 121d may be positioned between the plurality of substrate holders SH. Accordingly, the first to fourth support frames 121a, 121b, 121c and 121d may not interfere with the substrate holder SH even when the first to fourth support frames 121a, 121b, 121c and 121d are raised in the third-axis direction Z by the plurality of position adjustment portions 110.

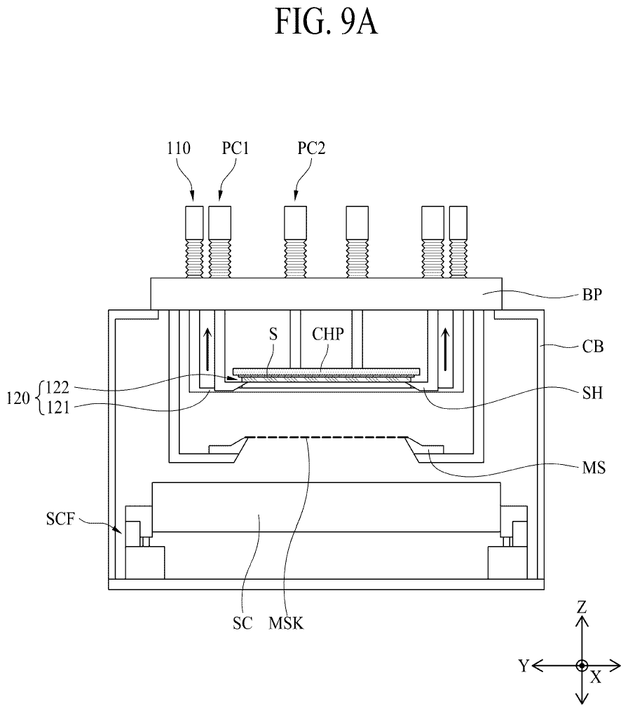

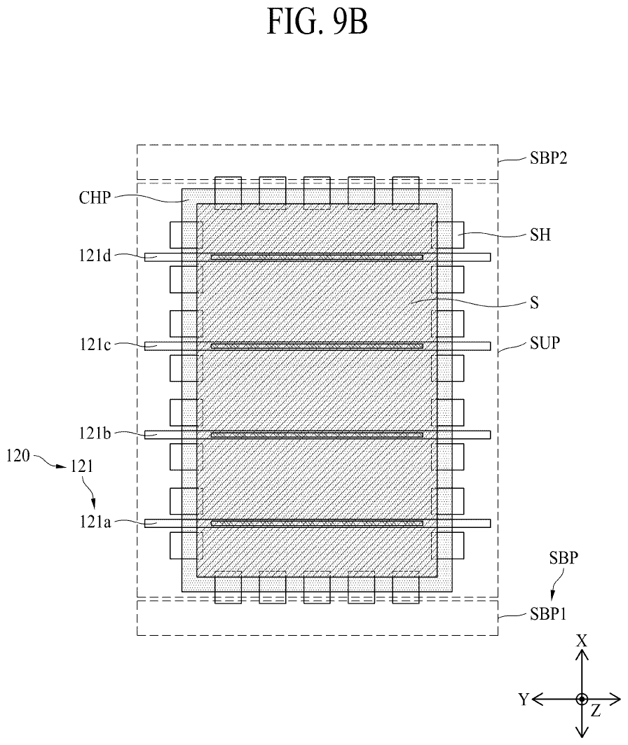

FIGS. 9A and 9B illustrate a step of chucking (or fixing) the substrate S to the chucking plate CHP by raising the plurality of support portions 120 to support the substrate S and applying the voltage to the chucking plate CHP. FIG. 9A is a schematic side view in an aspect of first-axis direction X, and FIG. 9B is a schematic plan view in an aspect of third-axis direction Z.

As shown in FIG. 9A, the plurality of support portions 120 may be raised in a direction toward the chucking plate CHP by the plurality of position adjustment portions 110. Thus, the support member 122 in each of the plurality of support portions 120 may be in contact with the lower surface (or central portion) of the substrate S. As the support member 122 moves upward, the lower surface (or central portion) of the substrate S may move upward. Therefore, the first distance between the edge of the substrate S and the chucking plate CHP may be similar to or may be the same as the second distance between the central portion of the substrate S and the chucking plate CHP. In this state, when the voltage (or static electricity) is applied to the chucking plate CHP, the central portion and the edge of the substrate S may be chucked (or fixed) to the chucking plate CHP.

FIG. 9B is a plan view showing the plurality of position adjustment portions 110 which raise the plurality of support portions 120 in a direction toward the chucking plate CHP and chuck (or fix) the plurality of support portions 120 to the chucking plate CHP. Thus, the features on the plane in FIG. 9B may be the same as those of FIG. 8B. Therefore, a description thereof is replaced with the description of FIG. 8B.

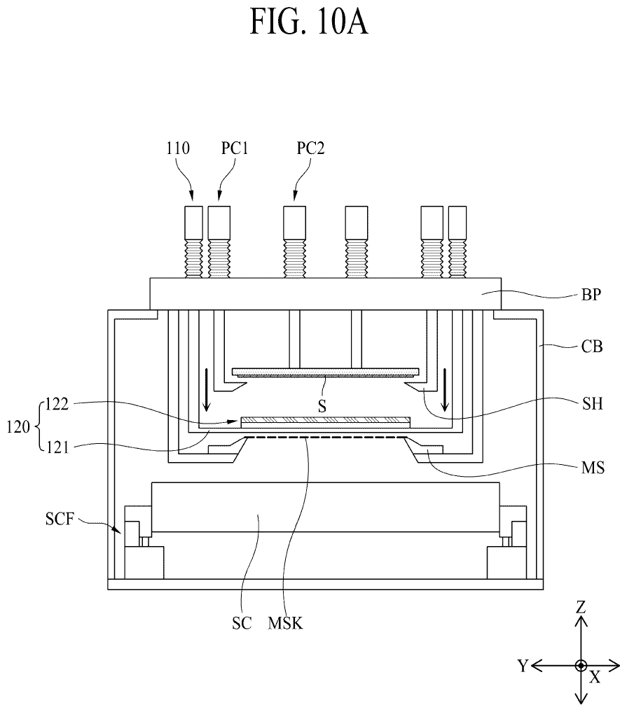

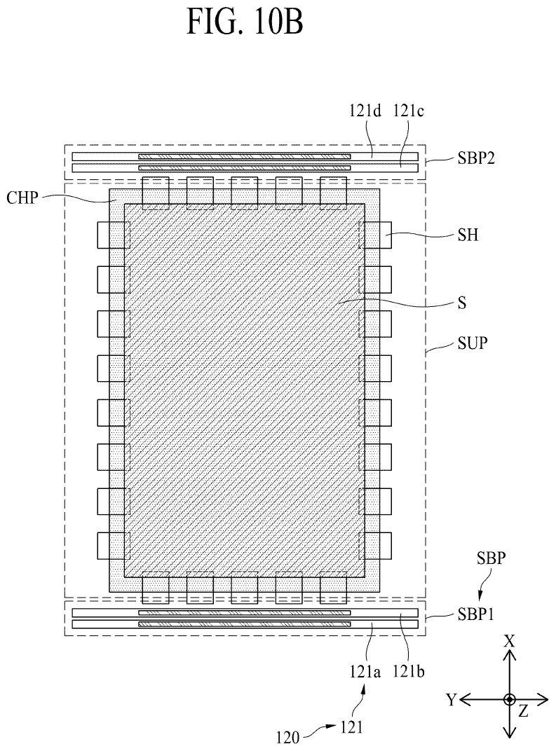

FIGS. 10A and 10B show the step of lowering and moving the plurality of support portions 120 to the standby position SBP. FIG. 10A is a schematic side view in an aspect of first-axis direction X, and FIG. 10B is a schematic plan view in an aspect of third-axis direction Z.

As shown in FIG. 10A, the plurality of position adjustment portions 110 may lower the plurality of support portions 120 in a direction toward the mask MSK. In this case, the substrate S may be fixed to the chucking plate CHP by static electricity. Thus, as shown in FIG. 10A, the substrate S may be positioned evenly. The plurality of support portions 120 may be located between the substrate holder SH and the mask MSK in the third-axis direction Z.

In FIG. 10B, in the state shown in FIG. 10A, the plurality of support portions 120 are moved along the pair of guide portions 130 to the standby position SBP. This may be performed by moving the plurality of support portions 120 along the pair of guide portions 130 from the support position SUP to the standby position SBP through the driving force provided from the plurality of rotation driving portions 140. Accordingly, the first support frame 121a and the second support frame 121b may be moved from the support position SUP to the first standby position SBP1, and the third support frame 121c and the fourth support frame 121d may be moved from the support position SUP to the second standby position SBP2. In this case, each of the first support frame 121a, the second support frame 121b, the third support frame 121c, and the fourth support frame 121d may not overlap the substrate S and/or the plurality of substrate holders SH. Thus, the first to fourth support frames 121a, 121b, 121c and 121d may not interfere between the source SC and the substrate S in the subsequent process of depositing the organic material. Accordingly, the organic material may be uniformly deposited on the entire surface of the substrate S so that it is possible to improve the quality of the substrate S in which the manufacturing process is completed.

Although not shown, the second position control portion PC2 lowers the chucking plate CHP and attaches the mask MSK having the opening OA to the lower surface of the substrate S for the subsequent process. The source SC may evaporate the organic material and may deposit the organic material on the substrate S exposed through the opening OA. Accordingly, the organic material may be deposited on the lower surface of the substrate S according to the shape of the opening OA of the mask MSK.

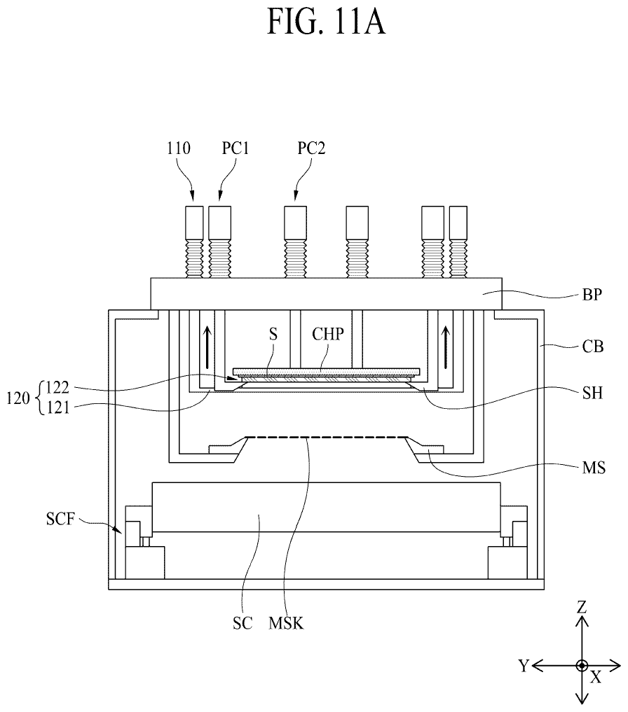

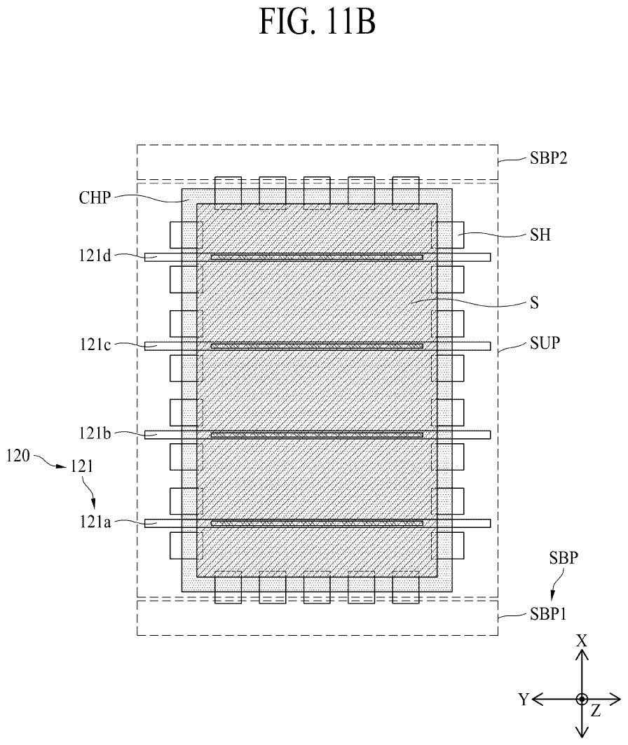

FIGS. 11A and 11B illustrate a step of supporting the substrate S on which the organic material is deposited by moving the plurality of support portions 120 to the support position SUP and raising the support portions 120. FIG. 11A is a schematic side view in an aspect of first axis direction, and FIG. 11B is a schematic plan view in an aspect of third-axis direction Z.

As shown in FIG. 11B, the plurality of support portions 120 may be moved from the standby position SBP to the support position SUP along the pair of guide portions 130 by the driving force provided by the plurality of rotation driving portions 140. In this case, the plurality of support portions 120 may be spaced apart from each other under the substrate S. For example, the first support frame 121a, the second support frame 121b, the third support frame 121c, and the fourth support frame 121d may be arranged at the same interval in the support position SUP, but not limited thereto. In this case, each of the first support frame 121a, the second support frame 121b, the third support frame 121c, and the fourth support frame 121d may be positioned between the plurality of substrate holders SH. Accordingly, the first to fourth support frames 121a, 121b, 121c and 121d may not interfere with the substrate holder SH even when the first to fourth support frames 121a, 121b, 121c and 121d are raised in the third-axis direction Z by the plurality of position adjustment portions 110.

As illustrated in FIG. 11A, in the state as shown in FIG. 11B, the plurality of position adjustment portions 110 raise the plurality of support portions 120 in a direction toward the chucking plate CHP. Thus, the support member 122 in each of the plurality of support portions 120 may be in contact with the lower surface (or central portion) of the substrate S and may support the lower surface (or central portion) of the substrate S. Thereafter, when the voltage (or static electricity) applied to the chucking plate CHP is turned-off, the substrate S on which the organic material is deposited may be supported only by the support member 122.

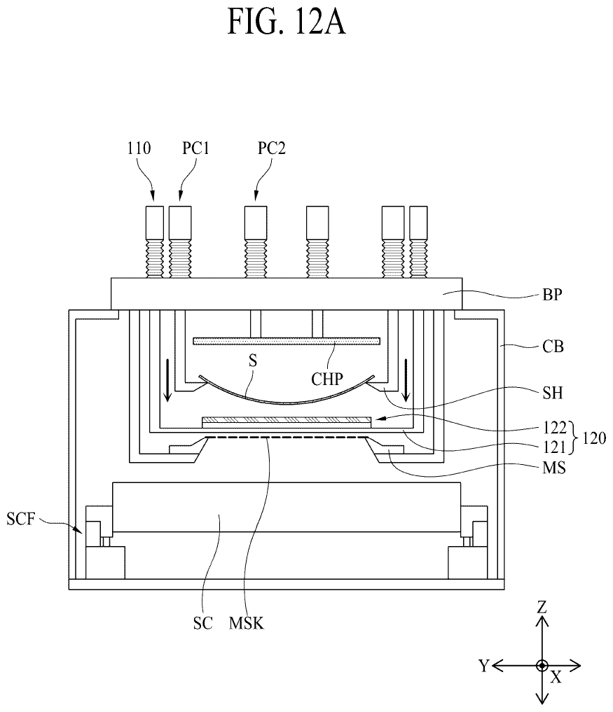

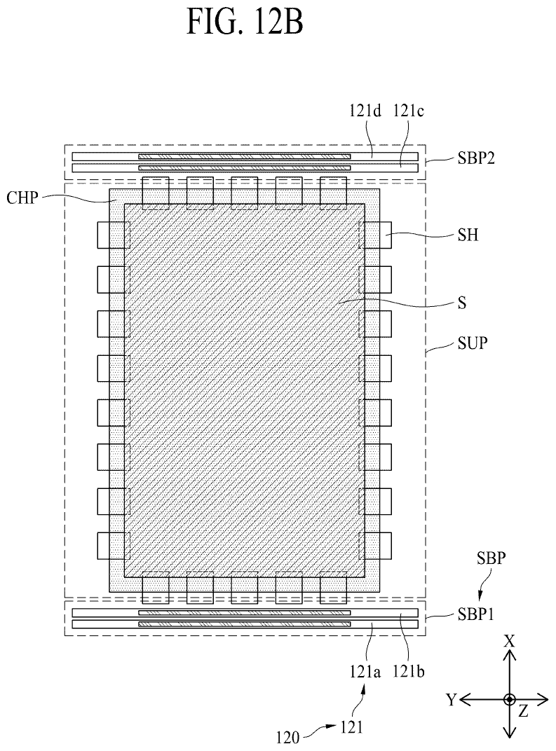

FIGS. 12A and 12B show a step of lowering the plurality of support portions 120 and supporting the edge of the substrate S, on which the organic material is deposited, on the substrate holder SH. FIG. 12A is a schematic side view in an aspect of first-axis direction X, and FIG. 12B is a schematic plan view in an aspect of third-axis direction Z.

As shown in FIG. 12A, the plurality of support portions 120 may be lowered in a direction toward the mask MSK by the plurality of position adjustment portions 110. In this case, the plurality of support portions 120 may be lowered further downward than the plurality of substrate holders SH. Accordingly, the edge of the substrate S supported by the support member 122 may be supported by the substrate holder SH, and the substrate S may be spaced apart from the support member 122. Therefore, as shown in FIG. 12A, the edge of the substrate S may be supported by the plurality of substrate holders SH, and the central portion of the substrate S may sag with its load. However, because the organic material is already deposited on the substrate S, the quality of the substrate S may be maintained even if the central portion of the substrate S is sagging. Meanwhile, as shown in FIG. 12A, the plurality of support portions 120 may be positioned between the substrate holder SH and the mask MSK in the third-axis direction Z.

In FIG. 12B, in the state as shown in FIG. 12A, the plurality of support portions 120 are moved to the standby position SBP. This may be performed by moving the plurality of support portions 120 along the pair of guide portions 130 from the support position SUP to the standby position SBP through the driving force provided from the plurality of rotation driving portions 140. Accordingly, the first support frame 121a and the second support frame 121b may be moved from the support position SUP to the first standby position SBP1, and the third support frame 121c and the fourth support frame 121d may be moved from the support position SUP to the second standby position SBP2. In this case, each of the first support frame 121a, the second support frame 121b, the third support frame 121c, and the fourth support frame 121d may not overlap the substrate S and/or the plurality of substrate holders SH. Accordingly, the substrate on which the organic material is deposited may be easily unloaded from the chamber CB by a transfer means, such as a robot.

As the substrate manufacturing method according to one embodiment of the present disclosure is performed by the substrate support apparatus 100 according to one embodiment of the present disclosure, the organic material may be uniformly deposited on the substrate S by easily (or evenly) fixing (or chucking) the substrate S (or large-sized substrate S) to the chucking plate CHP before the organic material deposition process. Therefore, the substrate manufacturing method according to one embodiment of the present disclosure minimizes, prevents, or at least reduces the sagging of the substrate S, thereby reducing the defect rate of the substrate and further reducing the production energy.

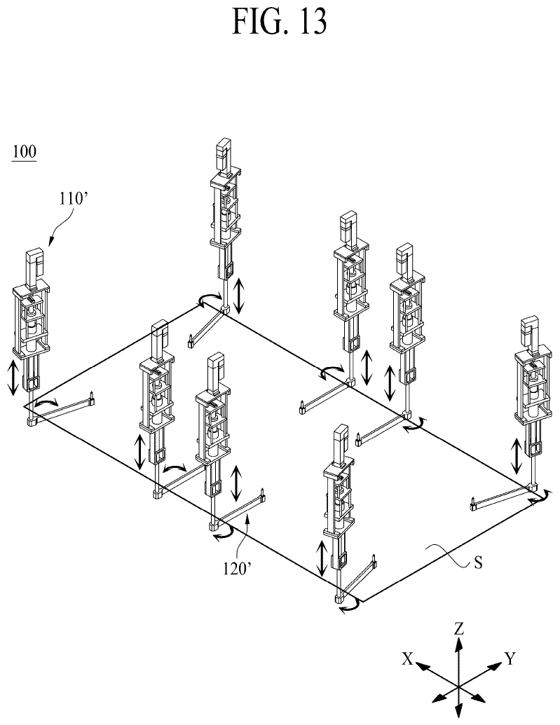

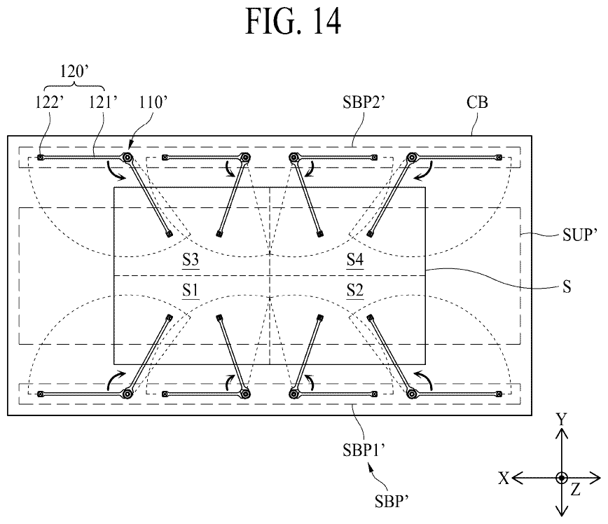

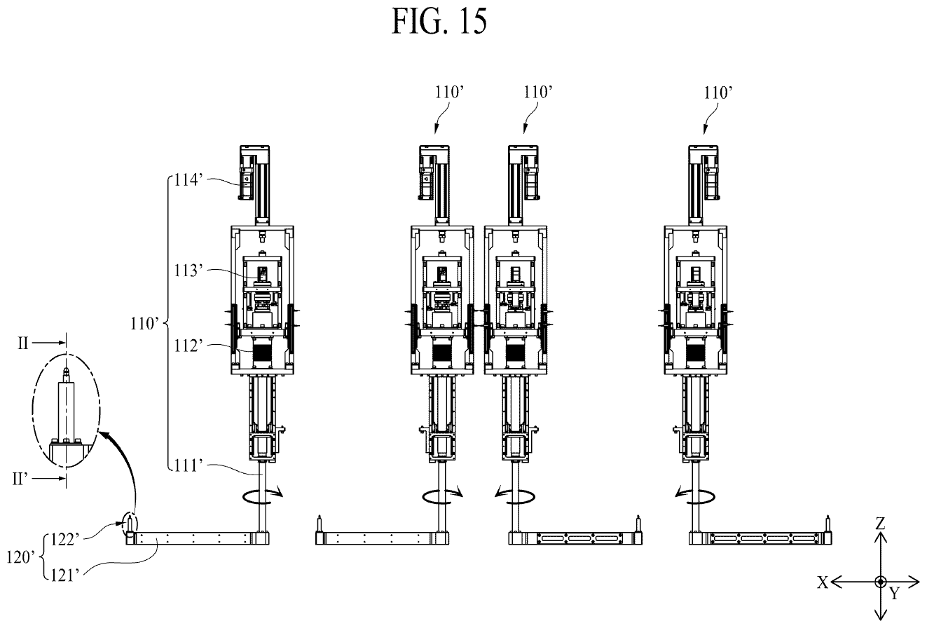

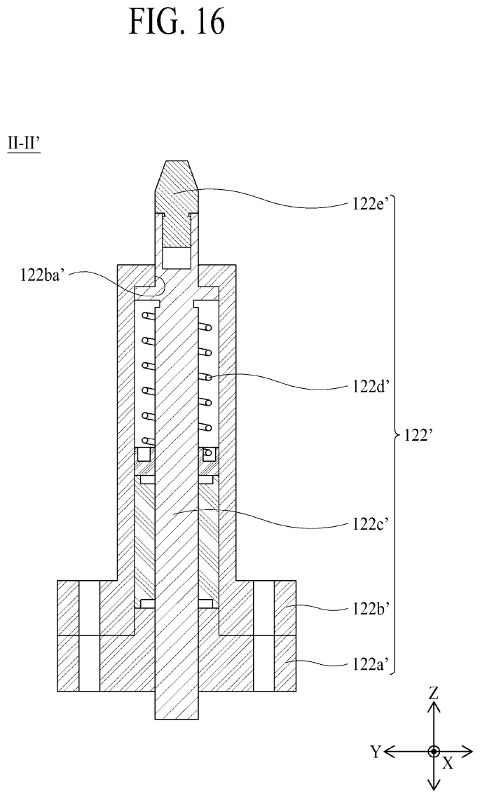

FIG. 13 is a perspective view illustrating a substrate support apparatus according to another example embodiment of the present disclosure, FIG. 14 is a schematic plan view of FIG. 13, FIG. 15 is a schematic side view of FIG. 13, and FIG. 16 is a cross-sectional view along II-II′ of FIG. 15.

With reference to FIGS. 13 to 16, the substrate support apparatus according to another embodiment of the present disclosure is the same as the substrate support apparatus of FIG. 1, except that the plurality of position adjustment portions 110 and the plurality of support portions 120 are changed in configuration, and the pair of guide portions 130 and the plurality of rotation driving portions 140 are omitted. Therefore, the same reference numerals are assigned to the same elements, and only different configurations will be described below.

In case of the substrate support apparatus according to FIG. 1 described above, the plurality of position adjustment portions 110 elevates the pair of guide portions 130, and the plurality of rotation driving portions 140 are connected to the pair of guide portions 130 and are configured to move the plurality of support portions 120 in the first-axis direction X. For examples, the substrate support apparatus according to FIG. 1 has the structure in which the plurality of position adjustment portions 110 are indirectly connected to the plurality of support portions 120 through the pair of guide portions 130. Therefore, with the substrate support apparatus according to FIG. 1, the plurality of support portions 120 are moved in the first-axis direction X and the third-axis direction Z by the plurality of position adjustment portions 110 and the plurality of rotation driving portions 140, thereby supporting the lower surface of the substrate (or central portion of the substrate S) in the support mode. Therefore, the substrate support apparatus of FIG. 1 may minimize or reduce sagging of the substrate S, thereby reducing the defect rate of the substrate S in which the manufacturing process is completed.

Meanwhile, in case of the substrate support apparatus according to FIG. 13, a plurality of position adjustment portions 110′ are directly connected to a plurality of support portions 120′. Therefore, in case of the substrate support apparatus according to FIG. 13, the plurality of support portions 120′ are rotated and raised by the plurality of position adjustment portions 110′, thereby supporting a lower surface (or central portion of the substrate S) of a substrate S in a support position SUP′ for a support mode. In addition, because the plurality of support portions 120′ are lowered and rotated by the plurality of position adjustment portions 110′, the plurality of support portions 120′ may be positioned in a standby position SBP′ which does not overlap the substrate S for a standby mode.

For example, in the substrate support apparatus according to FIG. 13, each of the plurality of position adjustment portions 110′ may include an elevating shaft 111′, a bellows 112′, a driving motor 113′, and an elevating motor 114′. Each of the plurality of support portions 120′ may include an arm frame 121′ and a pin assembly 122′.

The elevating shaft 111′ in each of the plurality of position adjustment portions 110′ may be coupled to each of the plurality of support portions 120′. According to another embodiment of the present disclosure, the elevating shaft 111′ may be coupled to one side of the arm frame 121′. The elevating shaft 111′ may be elevated by a driving force provided by the elevating motor 114′. As the elevating shaft 111′ moves up and down, the arm frame 121′ may be moved together.

The bellows 112′ may be coupled to the elevating shaft 111′ and may be configured to locally surround the elevating shaft 111′. The bellows 112′ is for maintaining a pressure difference between a chamber CB (shown in FIG. 7A) of a vacuum state and an atmospheric pressure outside the chamber. The bellows 112′ according to another embodiment of the present disclosure may be disposed outside the chamber CB. For example, the bellows 112′ may be arranged on a base plate BP coupled to an upper side of the chamber CB. As described above, the elevating shaft 111′ is elevated by the elevating motor 114′. Thus, when a portion of the chamber CB, to which the elevating shaft 111′ is movably connected, communicates with the outside, the inside of the chamber CB cannot be maintained in the vacuum state. Therefore, the bellows 112′ may be provided in such a way that a portion where the base plate BP and the elevating shaft 111′ are connected to each other is sealed. For example, the bellows 112′ may be provided in the form of corrugated circular accordion.

The driving motor 113′ is for rotating the elevating shaft 111′. According to another embodiment of the present disclosure, the driving motor 113′ may be arranged on the bellows 112′, as shown in FIG. 15. The driving motor 113′ may be coupled to the other side of the elevating shaft 111′. The arm frame 121′ may be coupled to one side of the elevating shaft 111′. The driving motor 113′ may rotate the elevating shaft 111′ by providing a driving force so that the elevating shaft 111′ may rotate clockwise or counterclockwise.

The elevating motor 114′ may be arranged on the driving motor 113′ and may elevate the driving motor 113′. According to another embodiment of the present disclosure, the elevating motor 114′ may be coupled to ¬-shaped motor housing and may be configured to provide a driving force capable of elevating the driving motor 113′. For example, a ball screw connected to the elevating motor may be rotated according to the driving force provided by the elevating motor 114′, whereby a cylinder rod connected to the ball screw may be elevated. As the cylinder rod elevates, the elevating motor 113′ connected to the cylinder rod may be elevated. As a result, the elevating shaft 111′ may be elevated.

Therefore, in the substrate support apparatus 100 according to another embodiment of the present disclosure, each of the plurality of position adjustment portions 110′ may elevate the plurality of support portions 120′ in the third-axis direction Z and may rotate the arm frame 121′ (or pin assembly 122′) to be positioned in each of the standby position SBP′ and the support position SUP′.

As illustrated in FIG. 15, each of the plurality of support portions 120′ may include an arm frame 121′ and a pin assembly 122′.

The arm frame 121′ may be coupled to an end (or one side) of the elevating shaft 111′. Because the elevating shaft 111′ is rotated by the driving motor 113′, the arm frame 121′ may be rotated. For example, as shown in FIG. 14, in case of the support mode, the two arm frames 121′ provided on the left in a first standby position SBP1′ may be rotated clockwise and may be changed to the support position SUP′, and the pin assembly 122′ provided at the end of each arm frame 121′ may be positioned in a first quadrant S1 of the substrate S. The two arm frames 121′ provided on the right in the first standby position SBP1′ may be rotated in a counterclockwise direction and may be changed to the support position SUP′, and the pin assembly 122′ provided at the end of each arm frame 121′ may be positioned in a second quadrant S2 of the substrate S. The two arm frames 121′ provided on the left in a second standby position SBP2′ may be rotated counterclockwise and may be changed to the support position SUP′, and the pin assembly 122′ provided at the end of each arm frame 121′ may be positioned in a third quadrant S3 of the substrate S. The two arm frames 121′ provided on the right in the second standby position SBP2′ may be rotated clockwise and may be changed to the support position SUP′, and the pin assembly 122′ provided at the end of each arm frame 121′ may be positioned in a four quadrant S4 of the substrate S. Therefore, the pin assembly 122′ provided at the end of each of the eight arm frames 121′ may be spaced apart from each other under the substrate S.

On the other hand, in the substrate support apparatus 100 according to another embodiment of the present disclosure, the pin assembly 122′ included in each of the plurality of support portions 120′ may be rotated sequentially or simultaneously by the driving motor 113′. As shown in FIG. 14, the arm frame 121′ of each of the plurality of support portions 120′ has a predetermined rotation region. Thus, when the two adjacent arm frames 121′ are rotated in different directions, the arm frames 121′ may be interfered with each other and may be damaged. Therefore, the substrate support apparatus 100 according to another embodiment of the present disclosure is provided such that the two arm frames 121′ adjacent to each other are sequentially or simultaneously rotated in the same direction with respect to a boundary portion of each of the first to fourth quadrants S1 to S4, so that the two arm frames 121′ adjacent to each other may be not interfered with each other outside one quadrant and may be easily changed between the support position SUP′ and the standby position SBP′.

As shown in FIG. 14, the arm frame 121′ and the pin assembly 122′ in each of the plurality of support portions 120′ may be disposed inside the chamber CB and may be rotated and elevated by the plurality of position adjustment portions 110′.

The pin assembly 122′ may be coupled to the arm frame 121′ and may be spaced apart from the elevating shaft 111′. The pin assembly 122′ according to one embodiment of the present disclosure may be coupled to the other end of the arm frame 121′, but not limited thereto. The pin assembly 121′ may be coupled to a position spaced apart from the other end of the arm frame 121′ in a direction facing one side without being coupled to the other end of the arm frame 121′ according to the size of the substrate S. Because the arm frame 121′ is rotated by the driving motor 113′, the pin assembly 122′ may be rotated together. The pin assembly 122′ may comprise a bottom flange 122a′, a pin housing 122b′, a pin guide shaft 122c′, a pin elastic member 122d′ and a support pin 122e′.

As shown in FIGS. 15 and 16, the bottom flange 122a′ may be coupled to the other end of the arm frame 121′ through a fastening member, such as a bolt. In this case, the fastening member may also be fastened to the pin housing 122b′ disposed above the bottom flange 122a′. Thus, the bottom flange 122a′ and the pin housing 122b′ may be coupled together to the arm frame 121′ by the fastening member.

The pin housing 122b′ may be formed in a cylindrical shape of which the inside is partially empty. The pin housing 122b′ may be coupled to the bottom flange 122a′ and may be configured to include a pin through hole 122ba′. The pin housing 122b′ according to one embodiment of the present disclosure may be coupled to the upper surface of the bottom flange 122′ through a fastening member. The pin through hole 122ba′ may be formed to pass through a middle portion of an upper side of the pin housing 122b′. The pin guide shaft 122c′ may partially protrude through the pin through hole 122ba′. The pin through hole 122ba′ is provided to be smaller than the size of a head portion of the pin guide shaft 122c′, thereby preventing the entire pin guide shaft 122c′ from being separated from the pin housing 122b′. The pin guide shaft 122c′ partially protruding through the pin through hole 122ba′ may be a portion disposed on the upper side of the head portion.

The pin guide shaft 122c′ may be movably coupled to the bottom flange 122a′ and the pin housing 122b′. As described above, the pin guide shaft 122c′ may comprise the head portion, and the head portion may be disposed within the pin housing 122b′. According to one embodiment of the present disclosure, the pin guide shaft 122c′ may be formed to be longer than the sum of the bottom flange 122a′ and the pin housing 122b′ in the third-axis direction Z. Accordingly, an upper end of the pin guide shaft 122c′ may protrude upward from the pin housing 122b′, and a lower end of the pin guide shaft 122c′ may protrude downward from the bottom flange 122a′.

The pin elastic member 122d′ partially surrounds the pin guide shaft 122c′ and may be supported by one side of the pin guide shaft 122c′ and the pin housing 122b′. The pin elastic member 122d′ according to one embodiment of the present disclosure surrounds the body under the head portion of the pin guide shaft 122c′ and may be supported by one side (or head portion) of the pin guide shaft 122c′ and the pin housing 122b′. Thus, when the support pin 122e′ supports the substrate S, the pin guide shaft 122c′ may be moved downward by the load of the substrate S, thereby contracting the pin elastic member 122d′. On the contrary, if the support pin 122e′ does not support the substrate S, the pin elastic member 122d′ may be extended by the elastic restoring force, thereby moving the pin guide shaft 122c′ in the upward direction.

The support pin 122e′ may be coupled to one end of the pin guide shaft 122c′ so as to face the pin elastic member 122d′. Herein, one end of the pin guide shaft 122c′ may refer to a portion protruding to the outside of the pin housing 122b′ through the pin through hole 122ba′. As shown in FIG. 16, the support pin 122e′ may be provided in a size which gradually increases from an upper side to a lower side, in which a lower portion thereof being coupled to one end of the pin guide shaft 122c′ may be smaller than that of one end of the pin guide shaft 122c′. Accordingly, the lower portion of the support pin 122e′ may be inserted into an insertion groove formed at one end of the pin guide shaft 122c′. As a result, as shown in FIG. 16, the support pin 122e′ may be disposed outside the pin housing 122b′, thereby supporting the lower surface of the substrate S for the support mode.

The head portion of the pin guide shaft 122c′ is larger than the size of the pin through hole 122ba′. Thus, even when the pin guide shaft 122c′ is moved upward by the extension of the pin elastic member 122d′, the pin guide shaft 122c′ may not be separated from the pin housing 122b′.

As shown in FIG. 16, because the pin guide shaft 122c′ to which the support pin 122e′ is coupled is supported by the pin elastic member 122d′, the pin guide shaft 122c′ may be moved downward when supporting the substrate S. Therefore, the substrate support apparatus 100 according to another embodiment of the present disclosure may absorb an impact generated when the support pin 122e′ supports the substrate S by the pin elastic member 122d′. Therefore, as a compared to a case which does not have the pin elastic member and cannot absorb an impact, the substrate support apparatus 100 according to another embodiment of the present disclosure may minimize, prevent, or at least reduce damage, such as scratches on the substrate S.

As a result, with the example substrate support apparatus 100, the support portion 120′ directly coupled to the position adjustment portion 110′ is rotated and raised by the position adjustment portion 110′, so that it is possible to support the lower surface (or central portion of the substrate S) of the substrate S for the support mode. Therefore, the substrate support apparatus 100 according to another embodiment of the present disclosure may minimize or reduce sagging of the substrate S, thereby reducing a defect rate of the substrate S in which the manufacturing process is completed.

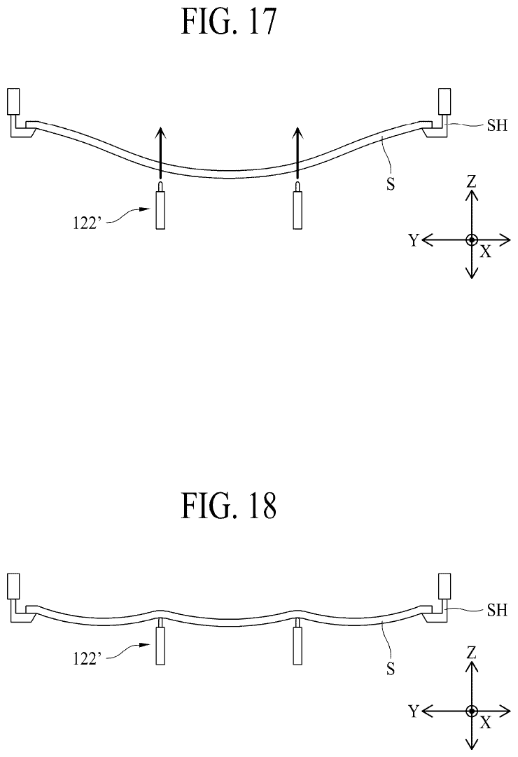

FIGS. 17 and 18 are schematic operation state diagrams for supporting the substrate by the substrate support apparatus according to another example embodiment of the present disclosure.

FIG. 17 is a diagram illustrating an operating state before the pin assembly 122′ supports the substrate S for the support mode. As shown in FIG. 17, the edge of the substrate S is supported on the substrate holder SH so that the central portion of the substrate S may sag downward due to the load. However, the substrate support apparatus 100 according to another embodiment of the present disclosure may support the sagging central portion of the substrate S through the plurality of position adjustment portions 110′ and the plurality of support portions 120′ and may move the sagging central portion of the substrate S upwardly.

FIG. 18 shows an operating state in which the pin assembly 122′ supports the substrate S for the support mode. As shown in FIG. 18, each of the plurality of pin assemblies 122′ is raised in the third-axis direction Z by each of the plurality of position adjustment portions 110′, so that the central portion of the substrate S may be supported and moved in the upward direction. Thus, the entire surface of the substrate S may be chucked (or fixed) to the chucking plate CHP by minimizing, preventing, or at least reducing the sagging of the substrate. Therefore, the substrate support apparatus 100 according to another embodiment of the present disclosure may uniformly deposit the organic material on the substrate S, thereby reducing the defect rate of the substrate S and further reducing the production energy according to the reduction of the defect rate of the substrate S.

A substrate manufacturing method using the substrate support apparatus 100 according to another embodiment of the present disclosure may be performed as follows.

First, the substrate S is inserted into the chamber CB using a transfer means, such as a robot, and the edge of the substrate S is supported by the plurality of substrate holders SH disposed inside the chamber CB. In this case, the pin assembly 122′ in the plurality of support portions 120′ may be positioned in the standby position SBP′ by the plurality of position adjustment portions 110′ while being not overlapped with the substrate S. For example, the four pin assemblies 122′ among the eight pin assemblies 122′ may be positioned in the first standby position SBP1′ by the plurality of position adjustment portions 110′, and the remaining four pin assemblies 122′ may be positioned in the second standby position SBP2′ by the plurality of position adjustment portions 110′. Accordingly, the substrate S inserted into the chamber CB may be stably placed on the substrate holder SH without interfering with the eight pin assemblies 122′.

Then, the plurality of pin assemblies 122′ are positioned in the support position SUP′. This process may be performed because the plurality of position adjustment portions 110′ rotate the arm frame 121′. Accordingly, the plurality of pin assemblies 122′ may be spaced apart from each other in the support position SUP′ under the substrate S. For example, the eight pin assemblies 122′ may be spaced apart from each other in the support position SUP′. In this case, each of the eight arm frames 121′ to which each of the eight pin assemblies 122′ is coupled may be positioned between the plurality of substrate holders SH. Accordingly, even if the eight arm frames 121′ are raised in the third-axis direction Z by the plurality of position adjustment portions 110′, the eight arm frames 121′ may not interfere with the substrate holder SH.

Under the state, the second position control portion PC2 lowers the chucking plate CHP positioned on the substrate S toward the substrate S. In this case, the chucking plate CHP may be positioned as close as possible to the edge of the substrate S so that it is possible to prevent or reduce the likelihood of the concavely provided edge of the substrate S from being damaged.

After that, the plurality of pin assemblies 122′ are raised to support the substrate S and the voltage is applied to the chucking plate CHP to chuck (or fix) the substrate S to the chucking plate CHP. This process may be performed by raising the plurality of pin assemblies 122′ in a direction toward the chucking plate CHP through the plurality of position adjustment portions 110′ and applying the voltage to the chucking plate CHP through a voltage supply portion (not shown) connected to the chucking plate CHP. Accordingly, the plurality of pin assemblies 122′ may be in contact with the lower surface (or central portion) the substrate S and may be further raised upward by the plurality of position adjustment portions 110′, to thereby prevent or reduce the substrate S from sagging. In this state, when the voltage (or static electricity) is applied to the chucking plate CHP, the central portion and the edge of the substrate S may be chucked (or fixed) to the chucking plate CHP.

Then, the plurality of pin assemblies 122′ are moved down and then rotated to be placed in the standby position SBP′. This process may be performed by lowering the plurality of pin assemblies 122′ toward the mask MSK through the plurality of position adjustment portions 110′ and rotating the arm frame 121′. In this case, the substrate S may be fixed to the chucking plate CHP by the static electricity. Therefore, the substrate S may be positioned evenly. The plurality of pin assemblies 122′ may be lowered by the plurality of position adjustment portions 110′ and be positioned between the substrate holder SH and the mask MSK in the third-axis direction Z. In this state, the plurality of pin assemblies 122′ may be moved to the standby position SBP′ because the arm frame 121′ is rotated by the driving force of the driving motor 113′.

Then, the second position control portion PC2 lowers the chucking plate CHP, whereby the mask MSK having the opening OA is attached to the lower surface of the substrate S. The source SC may evaporate the organic material, and the evaporated organic material is deposited on the substrate S exposed through the opening OA. Accordingly, the organic material may be deposited on the lower surface of the substrate S according to the shape of the opening OA of the mask MSK.

Then, the plurality of pin assemblies 122′ are rotated to be positioned in the support position SUP′ and are then raised to support the substrate S on which the organic material is deposited. This process may be accomplished by rotating the arm frame 121′ by the driving force provided from the driving motor 113′ and raising the elevating shaft 111′ by the driving force provided from the elevating motor 114′. Accordingly, the plurality of pin assemblies 122′ may be spaced apart from each other under the substrate S. In this case, each of the plurality of arm frames 121′ to which each of the plurality of pin assemblies 122′ is coupled may be positioned between the plurality of substrate holders SH. Therefore, even if the plurality of arm frames 121′ are raised in the third-axis direction Z by the plurality of position adjustment portions 110′, the plurality of arm frames 121′ may not interfere with the substrate holder SH. In this state, the plurality of pin assemblies 122′ may be raised in a direction toward the chucking plate CHP by the plurality of position adjustment portions 110′. Accordingly, the plurality of pin assemblies 122′ may be in contact with the lower surface (or central portion) of the substrate S, to thereby support the lower surface (or central portion) of the substrate S. Thereafter, when the voltage (or static electricity) applied to the chucking plate CHP is turned-off, the substrate S on which the organic material is deposited may be supported only by the plurality of pin assemblies 122′.

Then, the plurality of pin assemblies 122′ are lowered to support the edge of the substrate S, on which the organic material is deposited, on the substrate holder SH. This process may be accomplished by lowering the plurality of pin assemblies 122′ in a direction towards the mask MSK through the driving force provided from the elevating motor 114′. In this case, the plurality of pin assemblies 122′ may be lowered further downward than the plurality of substrate holders SH. Accordingly, the edge of the substrate S may be supported by the substrate holder SH, and the substrate S may be spaced apart from the plurality of pin assemblies 122′. The plurality of pin assemblies 122′ may be positioned between the substrate holder SH and the mask MSK in the third-axis direction Z. In this state, the plurality of pin assemblies 122′ may be moved to the standby position SBP′ by rotating the arm frame 121′ by the driving motor 113′. For example, the four pin assemblies 122′ of the eight pin assemblies 122′ may be moved from the support position SUP′ to the first standby position SBP1′, and the remaining four pin assemblies 122′ may be moved from the support position SUP′ to the second standby position SBP2′. In this case, each of the eight pin assemblies 122′ may not overlap the substrate S and/or the plurality of substrate holders SH. Accordingly, the substrate on which the organic material is deposited may be easily unloaded from the chamber CB by a transfer means, such as a robot.

The substrate manufacturing method according to another embodiment of the present disclosure is performed by the substrate support apparatus 100 according to another embodiment of the present disclosure, whereby the substrate S (or large-sized substrate S) may be easily (or evenly) fixed (or chucked) to the chucking plate CHP, and the organic material may be uniformly deposited on the substrate S. Therefore, the substrate manufacturing method according to another embodiment of the present disclosure minimizes, prevents, or at least reduces the sagging of the substrate, thereby reducing the defect rate of the substrate and further reducing the production energy.

According to the embodiments of the present disclosure, the substrate support apparatus may be provided with the support portion which supports the central portion of the substrate so that it is possible to provide the substrate support apparatus capable of minimizing or reducing sagging of the substrate and the method for manufacturing the substrate using the same.

According to the embodiment of the present disclosure, it is possible to provide the substrate support apparatus capable of minimizing or reducing sagging of the substrate and thus reducing the defect rate of the substrate and the method for manufacturing the substrate using the same.

According to the embodiment of the present disclosure, it is possible to provide the substrate support apparatus capable of reducing the production energy and the method for manufacturing the substrate using the same.

It will be apparent to those skilled in the art that various modifications and variations can be made in the substrate support apparatus and the method for manufacturing a substrate using the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A substrate support apparatus, comprising:
a plurality of position adjusters arranged in parallel and spaced apart with respect to a first direction; and
a plurality of supports connected to the plurality of position adjusters and configured to support a substrate,
wherein the plurality of supports are spaced apart from each other under the substrate and are configured to support the substrate, and
wherein the plurality of supports are configured to be raised by the plurality of position adjusters.

2. The substrate support apparatus according to claim 1, further comprising a pair of guides disposed along the first direction and connected to the plurality of position adjusters and the plurality of supports, respectively,
wherein the plurality of position adjusters are configured to elevate the pair of guides, and
wherein the plurality of supports are arranged along a second direction perpendicular to the first direction, and the plurality of supports are movably coupled to the pair of guides.

3. The substrate support apparatus according to claim 2, further comprising a plurality of rotation driver disposed in each of the pair of guides and configured to move the plurality of supports in the first direction.

4. The substrate support apparatus according to claim 2, wherein the plurality of position adjusters are spaced apart from each other along the pair of guides.

5. The substrate support apparatus according to claim 3, wherein each of the plurality of supports is moved by each of the plurality of rotation drivers so that the plurality of supports remain spaced apart from each other.

6. The substrate support apparatus according to claim 2,
wherein the pair of guides each include a plurality of standby positions in which the plurality of supports are disposed when the substrate is not supported and a support position at which the plurality of supports are configured to support the substrate, and
wherein each support position is between respective ones the plurality of standby positions.

7. The substrate support apparatus according to claim 3, wherein each of the plurality of supports includes:
a support frame movably coupled to each of the pair of guides; and
a support member coupled to the support frame,
wherein the support member has a length shorter than that of the support frame and is arranged in a longitudinal direction of the support frame.

8. The substrate support apparatus according to claim 7, wherein the support member includes:
a housing coupled to the support frame;
a stopper coupled to the housing and configured to have a through hole;
a guide shaft movably coupled to the stopper and the housing;
an elastic member configured to surround the guide shaft and supported by one side of the guide shaft and the housing; and
a support bar coupled to one side of the guide shaft to face the elastic member and partially protruding to the outside of the stopper through the through hole.

9. The substrate support apparatus according to claim 6, wherein the pair of guides have first and second ends with respect to the first direction, and wherein the plurality of supports include:
a first support frame at the first end of the pair of guides;
a second support frame disposed closer to the second end of the pair of guides than the first support frame;
a third support frame disposed closer to the second end of the pair of guides than the second support frame; and
a fourth support frame disposed closer to the second end of the pair of guides than the third support frame,
wherein the first support frame, the second support frame, the third support frame, and the fourth support frame are configured to be spaced apart from each other at the support position to support a substrate.

10. The substrate support apparatus according to claim 9, wherein the plurality of standby positions includes a first standby position at the first end of the pair of guides and a second standby position at the second end of the pair of guides,
wherein the first support frame and the second support frame are configured to be disposed at the first standby position when a substrate is not supported, and
wherein the third support frame and the fourth support frame are configured to be disposed at the second standby position when a substrate is not supported.

11. The substrate support apparatus according to claim 2, wherein each of the plurality of position adjusters includes:
an elevating shaft coupled to each of the pair of guides;
a bellows coupled to the elevating shaft and partially surrounding the elevating shaft; and
a cylinder pump disposed on the bellows and configured to move the elevating shaft up and down.

12. The substrate support apparatus according to claim 7, wherein each of the plurality of rotation drivers includes a ball screw disposed in each of the pair of guides, and a rotation motor configured to rotate the ball screw.

13. The substrate support apparatus according to claim 12, wherein each of the pair of guides includes:
a guide housing;
an LM guide coupled to the guide housing and disposed below the ball screw along a longitudinal direction of the ball screw; and
an LM block movably coupled to the LM guide and the ball screw and moved along the LM guide according to the rotation of the ball screw.

14. The substrate support apparatus according to claim 13, wherein each of the pair of guides further includes a guide hole into which one side or the other side of the support frame is inserted, and
wherein the guide hole is on the other side of the guide housing which is opposite to one side of the guide housing in which the support member is disposed.

15. The substrate support apparatus according to claim 14, wherein each of the plurality of supports further includes a separation preventing member coupled to a side of the support frame inserted into the guide hole, and
wherein a width of the separation preventing member is greater than a width of the guide hole.

16. The substrate support apparatus according to claim 2, wherein each of the plurality of position adjusters includes:
an elevating shaft coupled to each of the supports;
a bellows coupled to the elevating shaft and partially surrounding the elevating shaft;
a driving motor disposed on the bellows and configured to rotate the elevating shaft; and
an elevating motor disposed on the driving motor and configured to move the driving motor up and down.

17. The substrate support apparatus according to claim 16, wherein each of the plurality of supports includes:
an arm frame coupled to an end of the elevating shaft and configured to be rotated according to the rotation of the elevating shaft; and
a pin assembly coupled to the arm frame spaced apart from the elevating shaft,
wherein the pin assembly is configured to rotate according to the rotation of the arm frame.

18. The substrate support apparatus according to claim 17, wherein the pin assembly includes:
a bottom flange coupled to the arm frame;
a pin housing coupled to the bottom flange and configured to include a pin through-hole;
a pin guide shaft movably coupled to the bottom flange and the pin housing and partially protruding to the outside of the pin housing through the pin through-hole;
a pin elastic member partially surrounding the pin guide shaft and supported by one side of the pin guide shaft and the pin housing; and
a support pin coupled to one side of the pin guide shaft to face the pin elastic member.

19. The substrate support apparatus according to claim 17, wherein the pin assembly included in each of the plurality of supports is configured to sequentially or simultaneously rotate.

20. A method for manufacturing a substrate, comprising:
positioning a plurality of supports at a standby position so as not to overlap a substrate whose edge is supported on a substrate holder of a chamber;
positioning the plurality of supports to a support position and lowering a chucking plate disposed on the substrate;
supporting the substrate by raising the plurality of supports, and chucking the substrate to the chucking plate by applying a voltage to the chucking plate;
lowering the support portions and moving the supports to the standby position;
attaching a mask having an opening to the substrate by lowering the chucking plate, and evaporating an organic material from a source and depositing the organic material on the substrate;
supporting the substrate, on which the organic material is deposited, by moving the plurality of support portions to the support position and then raising the supports;
turning-off the voltage applied to the chucking plate; and
supporting the edge of the substrate on which the organic material is deposited on the substrate holder by lowering the plurality of supports.

21. A method for manufacturing a substrate comprising:
positioning a plurality of pin assemblies at a standby position not overlapping a substrate whose edge is supported on a substrate holder of a chamber;
rotating the plurality of pin assemblies to be positioned at a support position and lowering a chucking plate placed on the substrate;
supporting the substrate by raising the plurality of pin assemblies, and chucking the substrate to the chucking plate by applying a voltage to the chucking plate;
lowering and rotating the plurality of pin assemblies to be positioned at the standby position;
attaching a mask having an opening to the substrate by lowering the chucking plate, and evaporating an organic material from a source and depositing the organic material on the substrate;
supporting the substrate, on which the organic material is deposited, by moving the plurality of pin assemblies to the support position and then raising the pin assemblies;
turning-off the voltage applied to the chucking plate; and
supporting the edge of the substrate on which the organic material is deposited on the substrate holder by lowering the plurality of pin assemblies.
